(19) United States
(12) Patent Application Publication
(10) Pub. No.: US 2026/0262216 A1
(43) Pub. Date: Sep. 3, 2026

(54) SEMICONDUCTOR DEVICES

(71) Applicant: SAMSUNG ELECTRONICS CO., LTD., Suwon-si (KR)

(72) Inventors: Seryeun YANG, Suwon-si (KR); Jeonil LEE, Suwon-si (KR)

(73) Assignee: SAMSUNG ELECTRONICS CO., LTD., Suwon-si (KR)

(21) Appl. No.: 19/535,405

(22) Filed: Feb. 10, 2026

(30) Foreign Application Priority Data
Feb. 28, 2025 (KR) 10-2025-0026597

(51) Int. Cl. H10B 12/00; H10B 80/00; H10W 90/00; H10W 90/26

(52) U.S. Cl. CPC H10B 12/315; H10B 12/05; H10B 80/00; H10W 90/26; H10W 90/792

(57) ABSTRACT

A semiconductor device includes a bit line structure extending in a first direction, first, second, and third active patterns sequentially arranged on and connected to the bit line structure, a back gate structure between the first and second active patterns including a back gate dielectric layer and a back gate electrode, and a word line structure between the second and third active patterns. Contact patterns are disposed on and connected to the active patterns, and an information storage structure is disposed on the contact patterns. The bit line structure includes a first portion vertically overlapping the back gate structure and a second portion vertically overlapping the word line structure, with upper surfaces of the first and second portions disposed at different levels.

### CROSS-REFERENCE TO RELATED APPLICATION(S)

This application claims the benefit of priority to Korean Patent Application No. 10-2025-0026597 filed on February 28, 2025, in the Korean Intellectual Property Office, the disclosure of which is incorporated herein by reference in its entirety.

### BACKGROUND

The present disclosure relates to a semiconductor device, and a semiconductor device including a vertical channel transistor.

As demand for high performance, high speed, and/or multi-functionality of semiconductor devices increases, the integration of semiconductor devices increases. In manufacturing semiconductor devices having fine patterns corresponding to the trend toward high integration of semiconductor devices, it is required to implement patterns having fine widths or fine separation distances.

### SUMMARY

An aspect of the present disclosure is to provide semiconductor devices including a memory cell array formed using a bare wafer and including a structure in contact with a structure including a peripheral circuit.

However, the object of the present disclosure is not limited to the above-described objects, and may be variously extended without departing from the spirit and domain of the present disclosure.

A semiconductor device according to example embodiments of the present disclosure may include: a bit line structure extending in a first direction; back gate structures disposed on the bit line structure and respectively including a back gate electrode; word line structures disposed alternately with the back gate structures in the first direction, each of the word line structures including a first word line and a second word line, adjacent to each other in the first direction; active patterns disposed between the back gate structures and the word line structures and connected to the bit line structure; contact patterns disposed on each of the active patterns and connected to each of the active patterns; and information storage structures disposed on the contact patterns, and the bit line structure may include a first portion vertically overlapping each of the back gate structures, a second portion vertically overlapping each of the word line structures, and a third portion contacting each of the active patterns between the first portion and the second portion and having an inclined surface.

A semiconductor device according to example embodiments of the present disclosure may include: a bit line structure extending in a first direction; a first active pattern, a second active pattern, and a third active pattern sequentially arranged on the bit line structure in the first direction and connected to the bit line structure; a back gate structure disposed between the first active pattern and the second active pattern, and including a back gate dielectric layer and a back gate electrode disposed on the back gate dielectric layer; a word line structure disposed between the second active pattern and the third active pattern; contact patterns disposed on each of the first, second and third active patterns and connected to the first, second and third active patterns; and an information storage structure disposed on the contact patterns, and the bit line structure may include a first portion vertically overlapping the back gate structure and a second portion vertically overlapping the word line structure, and an upper surface of the first portion and an upper surface of the second portion are disposed at different levels.

A semiconductor device according to example embodiments of the present disclosure may include: a first structure including a memory cell array region; and a second structure vertically overlapping the first structure and including a peripheral circuit region, and the memory cell array region may include: a bit line structure extending in a first direction; a word line structure disposed on the bit line structure, and including a gate capping pattern and a first word line and a second word line, adjacent to each other in the first direction on the gate capping pattern; active patterns disposed on the bit line structure and disposed on both sides of the word line structure; insulating patterns disposed between each of the word line structures and each of the active patterns; contact patterns disposed on each of the active patterns and connected to each of the active patterns; and an information storage structure disposed on the contact patterns, and the bit line structure may include a portion having an inclined surface which is in contact with lower surfaces of each of the insulating patterns and has a vertical level that increases toward the word line structure.

A method of manufacturing a semiconductor device according to example embodiments of the present disclosure includes: preparing a semiconductor substrate; patterning the semiconductor substrate to form a trench structure, wherein the trench structure includes a first trench having a first width and a second trench, having the first width, below the first trench; forming a first substrate insulating pattern in the second trench and a first conductive pattern on the first substrate insulating pattern; forming a back gate structure in the first trench; removing a portion of the semiconductor substrate surrounding the first trench to form a body portion of the semiconductor substrate and protruding portions of the semiconductor substrate on both sides of the back gate structure, the protruding portions extending from the body portion; removing the body portion of the semiconductor substrate surrounding the second trench to expose a side surface of the first substrate insulating pattern and a side surface of the first conductive pattern, and forming a semiconductor layer of the semiconductor substrate remaining on a level lower than the second trench; forming a substrate insulating layer by forming a second substrate insulating pattern on a side surface of the first substrate insulating pattern on the semiconductor layer; forming a second conductive pattern on a side surface of the first conductive pattern on the second substrate insulating pattern to form a bit line structure; forming a word line structure on one side of the back gate structure on the bit line structure; forming contact patterns on protruding portions of the semiconductor substrate; and forming an information storage structure on the contact patterns.

According to an example embodiment, the forming the first trench may include: forming a first mask pattern including first openings extending in a first direction, and spaced apart from each other in a second direction, intersecting the first direction on the semiconductor substrate; forming a second mask pattern including second openings extending in the second direction, and spaced apart from each other in the first direction on the first mask pattern; forming the first trench by removing the first mask pattern exposed through the second openings and the semiconductor substrate below the first mask pattern; and forming an insulating liner on a sidewall of the first trench.

According to an example embodiment, the method further includes: forming auxiliary trenches by etching the semiconductor substrate exposed through the first openings; and forming a first insulating material within the auxiliary trenches

According to an example embodiment, the forming a back gate structure may include: forming a back gate dielectric layer conformally along a sidewall and a bottom surface of the first trench; forming a back gate electrode within the back gate dielectric layer; and forming a back gate capping pattern on the back gate electrode.

According to an example embodiment, the removing a portion of the semiconductor substrate surrounding the first trench may include: forming a first spacer layer conformally covering an upper surface of the semiconductor substrate and a side surface of the back gate dielectric layer exposed on the upper surface of the semiconductor substrate and an upper surface of the back gate capping pattern; and removing a first etched region of the first spacer layer covering the upper surface of the semiconductor substrate and the semiconductor substrate overlapping the first etched region.

According to an example embodiment, removing the body portion of the semiconductor substrate surrounding the second trench may include: forming a second spacer layer conformally covering an upper surface of the body portion, a side surface of the protruding portions and a side surface and an upper surface of the first spacer layer; and removing a second etched region of the second spacer layer covering the upper surface of the body portion, along with the body portion overlapping the second etched region.

According to an example embodiment, the removing the body portion surrounding the second trench may include forming the protruding portions as active patterns by separating the protruding portions from the body portion.

According to an example embodiment, a lower surface of each of the active patterns may be formed on a level lower than an upper surface of the first conductive pattern.

According to an example embodiment, the first substrate insulating pattern may include the same insulating material as the second substrate insulating pattern, and the first conductive pattern may include the same conductive material as the second conductive pattern.

According to an example embodiment, an upper surface of the second conductive pattern vertically overlapping the word line structure may be formed on a level higher than an upper surface of the first conductive pattern vertically overlapping the back gate structure.

A semiconductor device according to example embodiments of the present disclosure may include a memory cell array formed using a bare wafer. Accordingly, a semiconductor device having secured reliability may be provided, and a unit cost of a manufacturing process of the semiconductor device may be reduced.

Advantages and effects of the present application are not limited to the foregoing content and may be variously extended without departing from the spirit and domain of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic perspective view of a semiconductor device according to example embodiments of the present disclosure;

FIG. 2 is a plan view of a semiconductor device according to an example embodiment of the present disclosure;

FIG. 3 is a vertical cross-sectional view taken along line I-I' of the semiconductor device of FIG. 2 according to an example embodiment;

FIG. 4A is an enlarged view of region A of the semiconductor device of FIG. 3 according to an example embodiment.

FIGS. 4B to 4E are enlarged views of region A of the semiconductor device of FIG. 3 according to other example embodiments;

FIG. 5 is a vertical cross-sectional view taken along line I-I' of the semiconductor device of FIG. 2 according to another example embodiment;

FIG. 6 is a schematic perspective view of a semiconductor device according to another example embodiment;

FIG. 7 is a vertical cross-sectional view illustrating the semiconductor device of FIG. 6 according to an example embodiment; and

FIGS. 8A to 35 are cross-sectional views illustrating of a method of manufacturing the semiconductor device of FIG. 1 according to an example embodiment.

### DETAILED DESCRIPTION

Hereinafter, with reference to the attached drawings, a preferred example embodiment of the present disclosure will be described in more detail. The same reference numerals are used for the same components in the drawings, and duplicate descriptions of the same components are omitted.

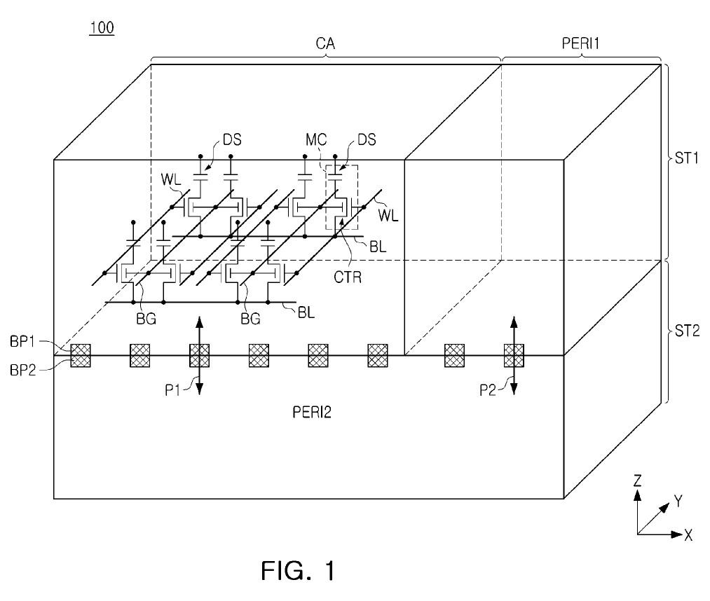

FIG. 1 is a schematic perspective view of a semiconductor device according to example embodiments of the present disclosure.

Referring to FIG. 1, a semiconductor device 100 may include a first structure ST1 and a second structure ST2 below the first structure STb. The first structure ST1 may include a memory cell array region CA and a first peripheral circuit region PERI1.

The memory cell array region CA may include a memory cell array. In an example embodiment, the memory cell array may include a plurality of bit lines BL, a plurality of word lines WL, a plurality of back gate lines BG, and a plurality of memory cells MC.

Each of the memory cells MC may include a cell transistor CTR and a data storage element DS. A memory cell MC may be disposed between one word line WL and one bit line BL. A cell array of the semiconductor device 100 may correspond to a memory cell array of a Dynamic Random Access Memory (DRAM) device.

The cell transistor CTR may include a gate, a source, and a drain. The gate may be connected to the word line WL, and the source may be connected to the bit line BL. The drain may be connected to a data storage element DS. The data storage element DS may include a capacitor formed of a lower electrode, an upper electrode and a dielectric layer.

The word lines WL may extend in a second direction (Y-direction) and may be spaced apart from each other in a first direction (X-direction). The word lines WL may be disposed on the same level and may be connected to different memory cells MC. Each of the bit lines BL may extend in the first direction (X-direction) and may be spaced apart from each other in the second direction (Y-direction).

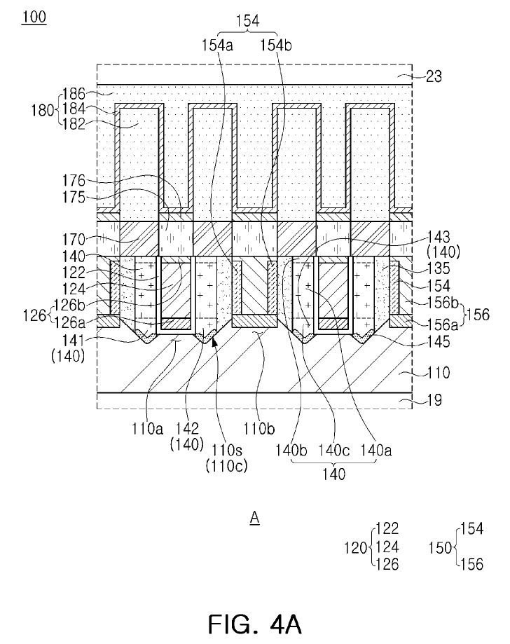

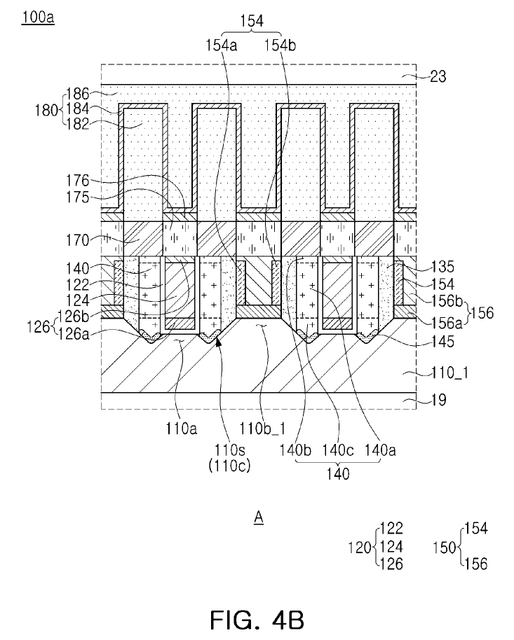

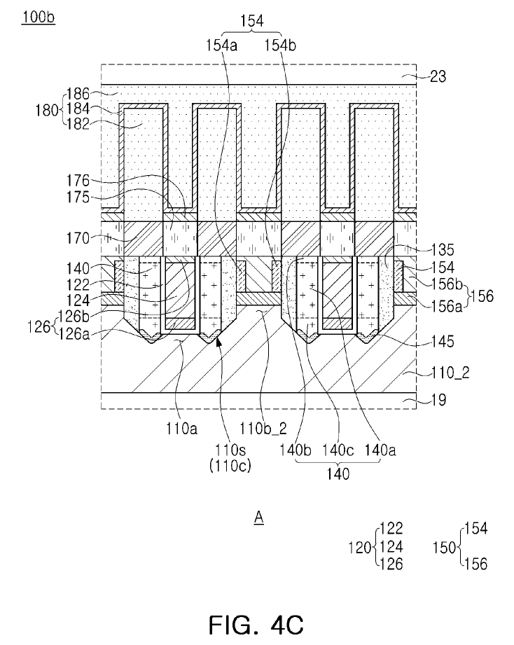

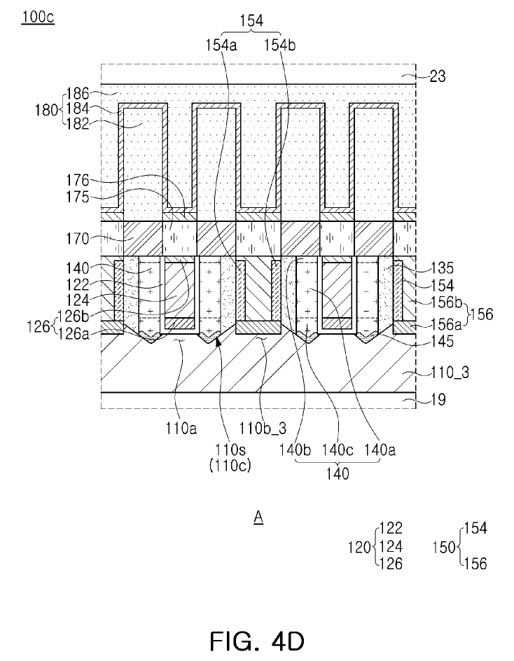

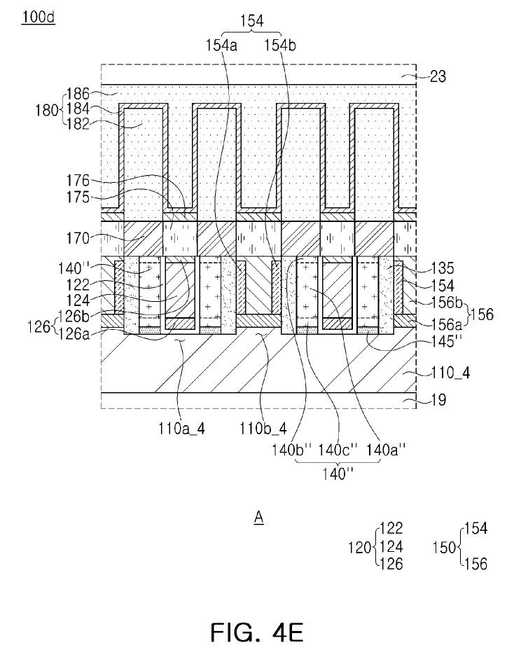

A back gate line BG may be disposed between two adjacent word lines WL. For example, the two adjacent word lines WL may share one back gate line BG. A voltage different from the voltage applied to the word lines WL may be applied to the back gate line BG. Channel regions (e.g., channel region 140a of FIG. 4A) of the cell transistor CTR may be floating bodies, and the back gate line BG may control charges accumulated in the channel regions, for example, holes. Accordingly, the floating body effect may be suppressed or controlled, and a threshold voltage of the cell transistor CTR may be prevented from changing. Accordingly, the back gate line BG may improve the electrical characteristics of the cell transistor CTR.

The back gate line BG may be independently and individually controlled by considering an interlayer characteristic distribution of the cell transistors CTR disposed in each layer. Alternatively, at least portions of the back gate lines BG may be electrically connected to each other and controlled together.

The first peripheral circuit region PERI1 may be spaced apart from the memory cell array region CA in the first direction (X-direction), and peripheral interconnection lines connected to peripheral transistors disposed in a second peripheral circuit region PERI2 may be disposed.

The second structure ST2 may overlap the first structure ST1 in a vertical direction (Z-direction). In an example, the second structure ST2 may be disposed below the first structure ST1 and may include the second peripheral circuit region PERI2. The second peripheral circuit region PERI2 may be disposed below the memory cell array region CA and the first peripheral circuit region PERI1, and may be electrically connected to the memory cell array region CA and the first peripheral circuit region PERI1. The second peripheral circuit region PERI2 may include peripheral circuit elements, and may include, for example, sub-word line drivers electrically connected to word lines WL and sense amplifiers electrically connected to bit lines BL.

The first structure ST1 may be bonded to the second structure ST2. For example, the first structure ST1 may include first bonding pads BP1 on a lower surface thereof, and the second structure ST2 may include second bonding pads BP2 on an upper surface thereof. The first bonding pads BP1 may be bonded to the second bonding pads BP2, and may electrically connect the first structure ST1 and the second structure ST2. For example, the first bonding pads BP1 and the second bonding pads BP2 may provide a first path P1 electrically connecting the memory cell array region CA and the second peripheral circuit region PERI2, and a second path P2 electrically connecting the first peripheral circuit region PERI1 and the second peripheral circuit region PERI2. The second peripheral circuit region PERI2 may include a first region overlapping the memory cell array region CA and a second region overlapping the first peripheral circuit region PERI1.

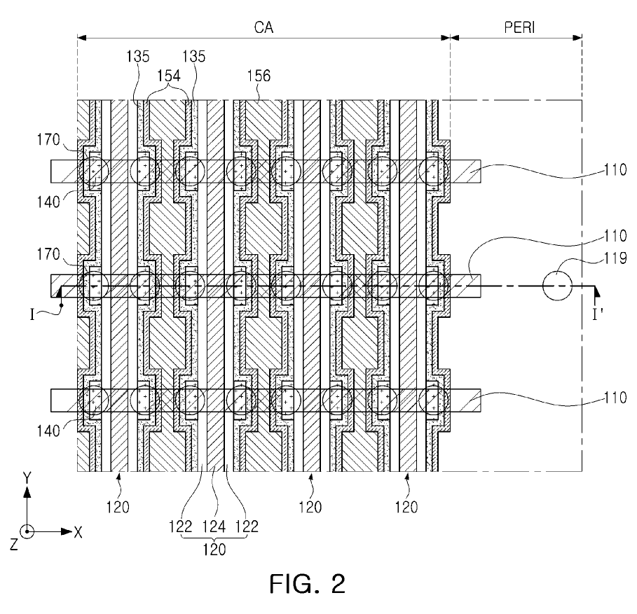

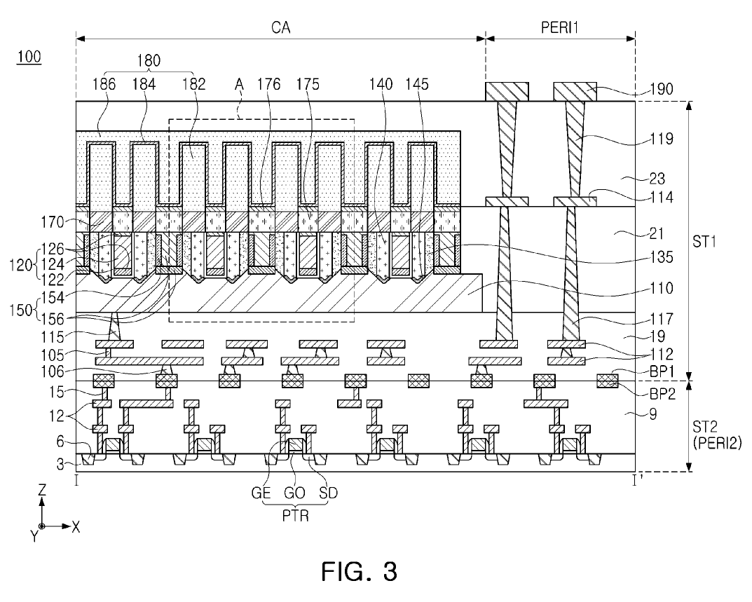

FIG. 2 is a plan view of a semiconductor device according to an example embodiment of the present disclosure. FIG. 3 is a vertical cross-sectional view taken along line I-I' of the semiconductor device of FIG. 2 according to an example embodiment. FIG. 4A is an enlarged view of region A of the semiconductor device of FIG. 3 according to an example embodiment.

Referring to FIGS. 2, 3 and 4A, the semiconductor device 100 may include a first structure ST1 and a second structure ST2 disposed below the first structure ST1. In an example, the memory cell array region CA and the first peripheral circuit region PERI1 may be disposed on the second peripheral circuit region PERI2 of the second structure ST2.

The memory cell array region CA of the semiconductor device 100 may include a bit line structure 110, back gate structures 120, active patterns 140, word line structures 150, contact patterns 170, and an information storage structure 180.

The memory cell array region CA may include a vertical channel transistor comprised of active patterns 140 and word lines 154 disposed on at least one side of the active patterns 140. The vertical channel transistor may correspond to the cell transistor CTR illustrated in FIG. 1.

Each of the bit line structures 110 may extend in the first direction (X-direction) and may be spaced apart from each other in the second direction (Y-direction). In an example, each of the bit line structures 110 may be electrically connected to the active patterns 140. Each of the bit line structures 110 may correspond to the bit line BL of FIG. 1.

The bit line structure 110 may include doped polysilicon, a metal, a conductive metal nitride, a metal-semiconductor compound, a conductive metal oxide, a conductive graphene, a carbon nanotube, or combinations thereof. For example, the bit line structure 110 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or combinations thereof.

The back gate structures 120 may intersect the bit line structures 110. Each of the back gate structures 120 may extend in the second direction (Y-direction) and may be spaced apart from each other in the first direction (X-direction). Each of the back gate structures 120 may be disposed on the bit line structure 110 and may include a back gate dielectric layer 122, a back gate electrode 124, and back gate capping patterns 126. In an example, each of the back gate electrodes 124 may extend in the second direction (Y-direction) and may be spaced apart from each other in the first direction (X-direction). The back gate electrode 124 may serve to remove charges trapped within the active pattern 140. The back gate electrode 124 may be a floating body, and the back gate electrode 124 may be a structure for supplementing the floating active pattern 140 to prevent or minimize performance degradation of the semiconductor device 100 due to the floating body effect of the active pattern 140.

The back gate electrode 124 may be formed of the same material as the word lines 154, but is not limited thereto and may include other materials. For example, the back gate electrode 124 may include doped polysilicon, a metal, a conductive metal nitride, a metal-semiconductor compound, a conductive metal oxide, graphene, a carbon nanotube, or combinations thereof. The back gate electrode 124 may be formed of a single layer or multiple layers of the materials described above. The back gate electrode 124 may correspond to the back gate line BG of FIG. 1.

The back gate dielectric layer 122 may extend in the second direction (Y-direction) along both side surfaces of the back gate electrode 124. A length of the back gate dielectric layer 122 in the vertical direction (Z-direction) may be greater than a vertical length of the back gate electrode 124. For example, an upper surface of the back gate dielectric layer 122 may be disposed on a higher level than an upper surface of the back gate electrode 124. A lower surface of the back gate dielectric layer 122 may be in contact with the bit line structure 110. The back gate dielectric layer 122 may include at least one of silicon oxide and a high-κ dielectric.

The back gate capping patterns 126 may include a lower back gate capping pattern 126a and an upper back gate capping pattern 126b spaced apart from the lower back gate capping pattern 126a in the vertical direction (Z-direction). The lower back gate capping pattern 126a may be disposed between a lower surface of the back gate electrode 124 and the back gate dielectric layer 122. The upper back gate capping pattern 126b may be disposed on the back gate electrode 124. In an example, a side surface and a lower surface of the lower back gate capping pattern 126a, a side surface of the back gate electrode 124, and a side surface of the upper back gate capping pattern 126b may be surrounded by the back gate dielectric layer 122. An upper surface of the upper back gate capping pattern 126b may be disposed on substantially the same level as an upper surface of the back gate dielectric layer 122. In an example, the upper surface of the upper back gate capping pattern 126b may be coplanar with an upper surface of the active pattern 140. In an example, the back gate capping patterns 126 may include silicon nitride.

The active patterns 140 may extend in the vertical direction (Z-direction), and in plan view, the active patterns 140 may be disposed on both side surfaces of each of the back gate structures 120. The active patterns 140 may be spaced apart from each other in the first direction (X-direction) and the second direction (Y-direction).

Each of the active patterns 140 may include a first source/drain region 140b connected to the contact pattern 170, a second source/drain region 140c in contact with the bit line structure 110, and a channel region 140a between the first source/drain region 140b and the second source/drain region 140c. In an example, the first source/drain region 140b and the second source/drain region 140c may have an N-type conductivity type. The active pattern 140 may correspond to the channel region and source/drain regions of the cell transistor CTR illustrated in FIG. 1. In this specification, the active pattern 140 may be referred to as a ‘cell channel structure’ or a ‘semiconductor pattern’.

Each of the active patterns 140 may include a first active pattern 141, a second active pattern 142 and a third active pattern 143 spaced apart from each other in the first direction (X-direction). In an example, the back gate structure 120 may be disposed between the first active pattern 141 and the second active pattern 142, and the word line structure 150 may be disposed between the second active pattern 142 and the third active pattern 143. In an example, one side of the first active pattern 141 may be in contact with the back gate dielectric layer 122 of the back gate structure 120, one side of the second active pattern 142 may be in contact with an insulating pattern 135, the other side facing the one side of the second active pattern 142 may be in contact with the back gate dielectric layer 122 of the back gate structure 120, and the other side of the third active pattern 143 may be in contact with the insulating pattern 135 disposed on both sides of the word line structure 150.

An upper surface of each of the active patterns 140 may be coplanar with an upper surface of the back gate structure 120 and an upper surface of the word line structure 150. For example, the upper surface of each of the active patterns 140 may be coplanar with the upper surface of the upper back gate capping pattern 126b of the back gate structure 120 and an upper surface of an upper gate capping pattern 156b of the word line structure 150.

A lower surface of each of the active patterns 140 may be disposed on a lower level than a lower surface of the back gate structure 120 and a lower surface of the word line structure 150. In an example, a vertical length from a lower surface of the bit line structure 110 to a lower surface of the active pattern 140 may be less than a vertical length from the lower surface of the bit line structure 110 to the lower surface of the back gate structure 120 (or the lower surface of the back gate dielectric layer 122). In an example, a vertical length from the lower surface of the bit line structure 110 to the lower surface of the active pattern 140 may be less than a vertical length from the lower surface of the bit line structure 110 to the lower surface of the word line structure 150 (or a lower surface of a lower gate capping pattern 156a).

A lower surface of each of the active patterns 140 may have a shape protruding toward the lower surface of the bit line structure 110. In an example, the lower surface of the active pattern 140 may have an inverted triangle shape narrowing toward the lower surface of the bit line structure 110.

A side surface of each of the active patterns 140 may include one side in contact with the back gate structure 120 and the other side opposing the one side and contacting the insulating pattern 135 described below.

The active pattern 140 may include a single crystal semiconductor material. The single crystal semiconductor material may include a group IV semiconductor, a group III-V compound semiconductor, or a group II-VI compound semiconductor, and may be, for example, a single crystal semiconductor including at least one of silicon, silicon carbide, germanium, or silicon-germanium.

The memory cell array region CA may further include a silicide pattern 145 disposed between the lower surface of the active pattern 140 and an upper surface of the bit line structure 110. The silicide pattern 145 may have a shape corresponding to a surface profile of the lower surface of the active pattern 140. In an example, the silicide pattern 145 may have a shape in which a width thereof becomes narrower toward the lower surface of the bit line structure 110. The silicide pattern 145 may be formed by contact between the lower surface of the active pattern 140 and the upper surface of the bit line structure 110, and the silicide pattern 145 may form a portion of the active pattern 140. The silicide pattern 145 may include a metal nitride such as titanium nitride (TiN) or a silicide material such as titanium silicide (TiSi). In an example, the silicide pattern 145 may form a portion of the active pattern 140.

Each of the word line structures 150 may intersect the bit line structures 110, may extend in the second direction (Y-direction), and may be spaced apart from each other in the first direction (X-direction). In an example, the word line structures 150 may be disposed alternately with the back gate structures 120 in the first direction (X-direction). Each of the word line structures 150 may include word lines 154 and gate capping patterns 156. The word lines 154 may include first and second word lines 154a and 154b, and the gate capping patterns 156 may include a lower gate capping pattern 156a and an upper gate capping pattern 156b disposed on the lower gate capping pattern 156a.

Each of the first and second word lines 154a and 154b may be disposed on the lower gate capping pattern 156a and may extend in the second direction (Y-direction) but may be spaced apart from each other in the first direction (X-direction). Each of the first and second word lines 154a and 154b may correspond to the word line WL of FIG. 1.

In an example embodiment, the lower surface of the word line structure 150 may be buried in the bit line structure 110. At least a portion of the lower gate capping pattern 156a may be buried in the upper surface of the bit line structure 110. However, the present disclosure is not limited thereto, and in this regard, reference will be made to FIGS. 4B to 4E, as described below. An upper surface of the lower gate capping pattern 156a may be disposed on a higher level than the upper surface of the bit line structure 110.

The word lines 154 may include doped polysilicon, a metal, a conductive metal nitride, a metal-semiconductor compound, a conductive metal oxide, conductive graphene, carbon nanotubes, or combinations thereof. For example, the word line 154 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or combinations thereof, but the present disclosure is not limited thereto. The word line 154 may include a single layer or multiple layers of the aforementioned materials.

The upper gate capping pattern 156b may extend in the second direction (Y-direction) between the first and second word lines 154a and 154b, and may cover upper surfaces of the first and second word lines 154a and 154b. An upper surface of the upper gate capping pattern 156b may be coplanar with the upper surface of the active pattern 140 and the upper surface of the upper back gate capping pattern 126b.

The gate capping pattern 156 may include silicon oxide, silicon nitride, silicon oxynitride, silicon carbonitride, a low-κ dielectric, or combinations thereof. In an example, the lower gate capping pattern 156a may include silicon nitride, and the upper gate capping pattern 156b may include silicon oxide. In some example embodiments, the lower gate capping pattern 156a and the upper gate capping pattern 156b may include the same material.

The memory cell array region CA may further include insulating patterns 135 disposed on both side surfaces of each of the word line structures 150. Each of the insulating patterns 135 may be disposed between the active pattern 140 and the word line structure 150. In an example, a side surface of each of the insulating patterns 135 may include one side in contact with the word line structure 150 and the other side opposing the one side and contacting the active pattern 140. In this document, the insulating pattern 135 may be referred to as a ‘gate spacer.’

An upper surface of each of the insulating patterns 135 may be coplanar with the upper surface of the active pattern 140, the upper surface of the back gate structure 120, and the upper surface of the word line structure 150.

A lower surface of each of the insulating patterns 135 may have an inclined surface in which a vertical level increases toward the word line structure 150. The lower surface of the insulating pattern 135 may be disposed on a higher level than the lower surface of the active pattern 140 and the lower surface of the back gate structure 120. In an example, the lower surface of the insulating pattern 135 may be in contact with a side surface of the lower gate capping pattern 156a. In the present specification, the insulating pattern 135 may be a tunnel dielectric layer that does not include an information storage layer. For example, the insulating pattern 135 may include at least one of silicon oxide or a high-κ dielectric. The high-κ dielectric may include a metal oxide or a metal oxynitride. For example, the high-κ dielectric may be formed of HfO₂, HfSiO, HfSiON, HfTaO, HfTiO, HfZrO, ZrO₂, Al₂O₃, or combinations thereof, but the present disclosure is not limited thereto.

Referring to FIG. 4A, the bit line structure 110 may include a first portion 110a overlapping the back gate structure 120, a second portion 110b overlapping the word line structure 150, and a third portion 110c having an inclined surface 110s between the first portion 110a and the second portion 110b.

In an example, the first portion 110a may be in contact with the lower surface of the back gate structure 120. The lower surface of the back gate dielectric layer 122 of the back gate structure 120 may be in contact with an upper surface of the first portion 110a. In an example, the second portion 110b may be in contact with the lower surface of the word line structure 150. A lower surface of the lower gate capping pattern 156a of the word line structure 150 may be buried in the second portion 110b. The word lines 154 may be spaced apart from the bit line structure 110 in the vertical direction (Z-direction) by the lower gate capping pattern 156a. That is, the lower surfaces of the first and second word lines 154a and 154b may be spaced apart from the bit line structure 110 in the vertical direction (Z-direction). In an example, the upper surface of the first portion 110a of the bit line structure 110 and an upper surface of the second portion 110b may be flat.

In an example, a lower surface of each of the active patterns 140 may be disposed on a lower level than the upper surface of the first portion 110a and the upper surface of the second portion 110b. That is, a lower surface of the silicide pattern 145 may be disposed on a lower level than the upper surface of the first portion 110a and the upper surface of the second portion 110b. In an example, the upper surface of the first portion 110a may be disposed on a different level from the upper surface of the second portion 110b. For example, the upper surface of the first portion 110a may be disposed on a lower level than the upper surface of the second portion 110b. In an example, a vertical length of the first portion 110a of the bit line structure 110 may be less than a vertical length of the second portion 110b of the bit line structure 110.

In an example, the third portion 110c of the bit line structure 110 may be disposed between the first portion 110a and the second portion 110b and may have an inclined surface 110s. The third portion 110c may overlap the active pattern 140 and the insulating pattern 135 disposed between the back gate structure 120 and the word line structure 150 in the vertical direction (Z-direction). An upper surface of the third portion 110c may correspond to a surface profile of the lower surface of the active pattern 140 and the lower surface of the insulating pattern 135. For example, the lower surface of the active pattern 140 may have a groove shape in which a width thereof becomes narrower toward a lower portion, and the lower surface of the insulating pattern 135 may have an inclined surface in which a vertical level thereof increases toward the word line structure 150.

In an example, a vertical level of the inclined surface 110s of the third portion 110c may increase toward the word line structure 150. In an example, a maximum vertical length of the third portion 110c may be greater than a vertical length of the second portion 110b, and a minimum vertical length of the third portion 110c may be less than a vertical length of the first portion 110a.

The contact patterns 170 may be disposed on the active patterns 140 and may be electrically connected to the active patterns 140. The contact patterns 170 may electrically connect the active patterns 140 and the information storage structure 180.

Lower surfaces of the contact patterns 170 are illustrated as being in contact with the active patterns 140, the back gate dielectric layer 122 and the insulating pattern 135, but according to example embodiments, the lower surfaces of the contact patterns 170 may also be in contact with the upper gate capping pattern 156b and/or the upper back gate capping pattern 126b.

The contact patterns 170 may include a conductive material, such as doped single crystal silicon, doped polycrystalline silicon, a metal, a conductive metal nitride, a metal-semiconductor compound, a conductive metal oxide, conductive graphene, carbon nanotubes, or combinations thereof. In an exemplary embodiment, the contact patterns 170 may include a first contact layer including polycrystalline silicon and a second contact layer disposed on the first contact layer and including a silicide material. In another example, the contact patterns 170 may include a first contact layer including a silicide material and a second contact layer disposed on the first contact layer and including a metal material. However, according to example embodiments, the number of layers and the type of material of the contact patterns 170 may be variously changed.

The memory cell array region CA may further include first contact insulating patterns 175 disposed between the contact patterns 170. Each of the first contact insulating patterns 175 may extend vertically and contact the word line structure 150. The first contact insulating patterns 175 may spatially separate the contact patterns 170 and electrically insulate the contact patterns 170.

The memory cell array region CA may further include second contact insulating patterns 176 disposed on the first contact insulating patterns 175.

The information storage structure 180 may include first electrodes 182 electrically connected to the contact patterns 170, second electrodes 186 covering the first electrodes 182, and a dielectric layer 184 between the first electrodes 182 and the second electrodes 186. The information storage structure 180 may completely overlap or partially overlap the contact patterns 170 in the vertical direction (Z-direction). The first electrodes 182 may be disposed on the contact patterns 170 by penetrating through the second contact insulating pattern 176. The information storage structure 180 may correspond to the data storage element DS of FIG. 1.

The information storage structure 180 may be a capacitor for storing information in a DRAM. For example, the dielectric layer 184 of the information storage structures 180 may be a capacitor dielectric layer of the DRAM, and the dielectric layer 184 may include a high-κ dielectric, silicon oxide, silicon nitride, silicon oxynitride, or combinations thereof.

The information storage structure 180 may be a structure for storing information of a memory other than the DRAM. For example, the dielectric layer 184 of the information storage structures 180 may be a capacitor dielectric layer of a ferroelectric memory (FeRAM). In this case, the dielectric layer 184 may be a ferroelectric layer capable of recording data using a polarization state. Additionally, in another example embodiment, the dielectric layer 184 may include a lower dielectric layer including at least one of silicon oxide or a high-κ dielectric, and a ferroelectric layer disposed on the lower dielectric layer.

The first structure ST1 may further include a lower insulating layer 19, interconnection layers 112, vias 105, contact vias 106, and first bonding pads BP1, disposed below the bit line structure 110. The memory cell array region CA may further include a bit line contact via 115, and the first peripheral circuit region PERI1 may further include a first upper insulating structure 21 disposed on the lower insulating layer 19 on a side surface of the bit line structure 110, a second upper insulating structure 23 on the first upper insulating structure 21, connection pads 114 disposed on the first upper insulating structure 21, upper pads 190 disposed on the second upper insulating structure 23, a lower contact plug 117 connecting the interconnection layers 112 and the connection pads 114, and an upper contact plug 119 connecting the connection pads 114 and the upper pads 190.

The lower insulating layer 19 may be in contact with the lower surface of the bit line structure 110. The vias 105 may connect the interconnection layers 112, the contact vias 106 may connect the interconnection layers 112 and the first bonding pads BP1, and the bit line contact vias 115 may connect the interconnection layers 112 and the bit line structure 110. The interconnection layers 112, the vias 105, the contact vias 106 and the bit line contact vias 115 may be buried in the lower insulating layer 19. Each of the vias 105, the contact vias 106 and the bit line contact vias 115 may have a shape in which a width thereof becomes narrower toward an upper portion thereof, and the lower insulating layer 19 may be disposed in a plurality of layers.

The first upper insulating structure 21 may be disposed on the lower insulating layer 19 and may be disposed on a side surface of the cell transistor CTR of FIG. 1. The lower contact plug 117 may penetrate through the lower insulating layer 19 and the first upper insulating structure 21 disposed in an upper portion of the interconnection layer 112 to connect the interconnection layer 112 and the connection pad 114. The lower contact plug 117 may have a shape in which a width decreases toward the upper portion.

The second upper insulating structure 23 may cover a side surface and an upper surface of the information storage structure 180 on the first upper insulating structure 21. The upper contact plug 119 may connect the upper pad 190 and the connection pad 114 by penetrating through the second upper insulating structure 23. The upper contact plug 119 may have a shape in which a width decreases toward a lower portion. The upper pads 190 may be input/output pads.

The lower insulating layer 19 and the first and second upper insulating structures 21 and 23 may include silicon oxide or silicon nitride.

The first bonding pads BP1 may be disposed along a lower surface of the lower insulating layer 19. For example, lower surfaces of the first bonding pads BP1 may be coplanar with the lower surface of the lower insulating layer 19. At least portions of the first bonding pads BP1 may be connected to the contact vias 106.

The second peripheral circuit region PERI2 of the second structure ST2 may include a peripheral element isolation layer 6 and a peripheral transistor PTR disposed on an upper surface of a second substrate 3.

The second substrate 3 may include a semiconductor material, for example, a group IV semiconductor, a group III-V compound semiconductor, or a group II-VI compound semiconductor. For example, the group IV semiconductor may include silicon, germanium, or silicon-germanium. The second substrate 3 may further include impurities. The second substrate 3 may be a silicon substrate, a silicon-on-insulator (SOI) substrate, a germanium substrate, a germanium-on-insulator (GOI) substrate, a silicon-germanium substrate, or a substrate including an epitaxial layer.

The peripheral element isolation layer 6 may define peripheral active regions within the second substrate 3 and may extend downwardly from the upper surface of the second substrate 3. The peripheral element isolation layer 6 may include an insulating material. For example, the peripheral element isolation layer 6 may include silicon oxide, silicon nitride, silicon oxynitride, or combinations thereof, and may be formed of a single layer or multiple layers.

The peripheral transistor PTR may include peripheral source/drain regions SD, a peripheral gate dielectric layer GO, and a peripheral gate electrode GE. The peripheral transistor PTR may be a planar type transistor. For example, the peripheral source/drain regions SD may be disposed on the upper surface of the second substrate 3, and the channel region of the peripheral transistor PTR may be disposed between the peripheral source/drain regions SD. The channel region may be coplanar with upper surfaces of the peripheral source/drain regions SD and may be in contact with a lower surface of the peripheral gate electrode GE. The peripheral transistor PTR may be a component of the sub-word line drivers and sense amplifiers described above.

The second structure ST2 may further include an upper insulating layer 9, interconnection layers 12, vias 15, and second bonding pads BP2 disposed on the second substrate 3. The upper insulating layer 9 may cover the upper surface of the second substrate 3 and may cover the peripheral transistor PTR. The interconnection layers 12 may be buried in the upper insulating layer 9 and may be disposed in a plurality of layers. The vias 15 may electrically connect the interconnection layers 12.

The second bonding pads BP2 may be disposed along an upper surface of the upper insulating layer 9. For example, upper surfaces of the second bonding pads BP2 may be coplanar with the upper surface of the upper insulating layer 9. The second bonding pads BP2 may be bonded to the first bonding pads BP1. Each of the second bonding pads BP2 may be electrically connected to at least one of the interconnection layers 12 or the vias 15, respectively. Additionally, the peripheral transistor PTR may be electrically connected to at least one of the interconnection layers 12 or the vias 15.

The bonding of the first and second bonding pads BP1 and BP2 may be, for example, copper (Cu)-to-copper (Cu) bonding. However, the present disclosure is not limited thereto, and the first and second structures ST1 and ST2 of the semiconductor device 100 may be bonded by hybrid bonding including copper (Cu)-to-copper (Cu) bonding and dielectric-to-dielectric bonding.

FIGS. 4B to 4E are enlarged views of region A of the semiconductor device of FIG. 3 according to other example embodiments.

Referring to FIG. 4B, a semiconductor device 100a may include a bit line structure 110_1. The remaining components illustrated in FIG. 4B, except for the bit line structure 110_1, may be identical to or corresponding to the components illustrated in FIG. 3. The bit line structure 110_1 may include a first portion 110a vertically overlapping the back gate structure 120, a second portion 110b_1 vertically overlapping the word line structure 150, and a third portion 110c disposed between the first portion 110a and the second portion 110b_1 and having an inclined surface 110s. In an example, an upper surface of the first portion 110a and an upper surface of the second portion 110b may be flat. In an example, the upper surface of the first portion 110a may be in contact with the lower surface of the back gate structure 120. The word line structure 150 may be disposed on the upper surface of the second portion 110b_1. The upper surface of the second portion 110b_1 may be coplanar with the lower surface of the lower gate capping pattern 156a of the word line structure 150. In an example, a vertical length of the first portion 110a may be less than a vertical length of the second portion 110b_1. In an example, a maximum vertical length of the third portion 110c may be substantially the same as a vertical length of the second portion 110b_1.

In an example, the third portion 110c of the bit line structure 110_1 may overlap the active pattern 140 and the insulating pattern 135 in the vertical direction (Z-direction), and the lower surface of the active pattern 140 may have a shape protruding toward a lower surface of the third portion 110c of the bit line structure 110_1, and the lower surface of the insulating pattern 135 may have an inclined surface corresponding to an inclined surface profile of the third portion 110c.

Referring to FIG. 4C, a semiconductor device 100b may include a bit line structure 110_2. The remaining components illustrated in FIG. 4C, except for the bit line structure 110_2, may be identical to or corresponding to the components illustrated in FIG. 3. In an example, the bit line structure 110_2 may include a first portion 110a vertically overlapping the back gate structure 120, a second portion 110b_2 vertically overlapping the word line structure 150, and a third portion 110c disposed between the first portion 110a and the second portion 110b_2 and having an inclined surface 110s. In an example, an upper surface of the first portion 110a and an upper surface of the second portion 110b_2 may have a flat shape.

In an example, the back gate structure 120 may be disposed on the upper surface of the first portion 110a, and the word line structure 150 may be disposed on the upper surface of the second portion 110b_2. In an example, a vertical length of the first portion 110a may be less than a vertical length of the second portion 110b_2. The second portion 110b_2 may be in contact with a portion of a side surface of the insulating pattern 135. The upper surface of the second portion 110b_2 may be disposed on a higher level than the inclined surface 110s of the third portion 110c. For example, a maximum vertical length of the inclined surface 110s of the third portion 110c may be less than a vertical length of the second portion 110b_2.

Referring to FIG. 4D, a semiconductor device 100c may include a bit line structure 110_3. The remaining components illustrated in FIG. 4D except for the bit line structure 110_3 may be identical as or corresponding to the components illustrated in FIG. 3. In an example, the bit line structure 110_3 may include a first portion 110a vertically overlapping the back gate structure 120, a second portion 110b_3 vertically overlapping the word line structure 150, and a third portion 110c disposed between the first portion 110a and the second portion 110b_3 and having an inclined surface 110s.

The lower surface of the word line structure 150 may be buried in the second portion 110b_3. In an example, an upper surface of the first portion 110a may be disposed on substantially the same level as an upper surface of the second portion 110b_3. That is, a vertical length of the first portion 110a may be substantially the same as a vertical length of the second portion 110b_3. In an example, the lower surface of the back gate structure 120 and the lower surface of the word line structure 150 may be disposed on the same level. In an example, the third portion 110c may overlap the active pattern 140 and the insulating pattern 135 in the vertical direction (Z-direction), and may be in contact with a side surface of the lower gate capping pattern 156a of the word line structure 150.

In another example embodiment, the lower surface of the word line structure 150 may be buried in the second portion 110b_3. In an example, the upper surface of the first portion 110a may be disposed on a higher level than the upper surface of the second portion 110b_3. That is, a vertical length of the first portion 110a may be greater than a vertical length of the second portion 110b_3. In an example, the lower surface of the back gate structure 120 may be disposed on a higher level than the lower surface of the word line structure 150.

Referring to FIG. 4E, a semiconductor device 100d may include active patterns 140”, silicide patterns 145”, and bit line structures 110_4. The remaining components, except for the active patterns 140”, silicide patterns 145” and bit line structures 110_4, may be identical or correspond to the components illustrated in FIG. 3. In an example, the bit line structure 110_4 may include a first portion 110a_4 vertically overlapping the back gate structure 120, the active pattern 140” and the insulating pattern 135, and a second portion 110b_4 vertically overlapping the word line structure 150.

In an example, each of an upper surface of the first portion 110a_4 and an upper surface of the second portion 110b_4 may have a flat shape. The upper surface of the first portion 110a_4 may be in contact with the lower surface of the back gate structure 120, a lower surface of the silicide pattern 145”, and the lower surface of the insulating pattern 135. The lower surface of the back gate structure 120, the lower surface of the silicide pattern 145” and the lower surface of the insulating pattern 135 may form a coplanar surface.

In an example, the upper surface of the first portion 110a_4 may be disposed on a lower level than the upper surface of the second portion 110b_4. A vertical length of the first portion 110a_4 may be less than a vertical length of the second portion 110b_4. In an example, the lower surface of the word line structure 150 may be disposed on a higher level than the lower surface of the back gate structure 120, the lower surface of the silicide pattern 145” and the lower surface of the insulating pattern 135.

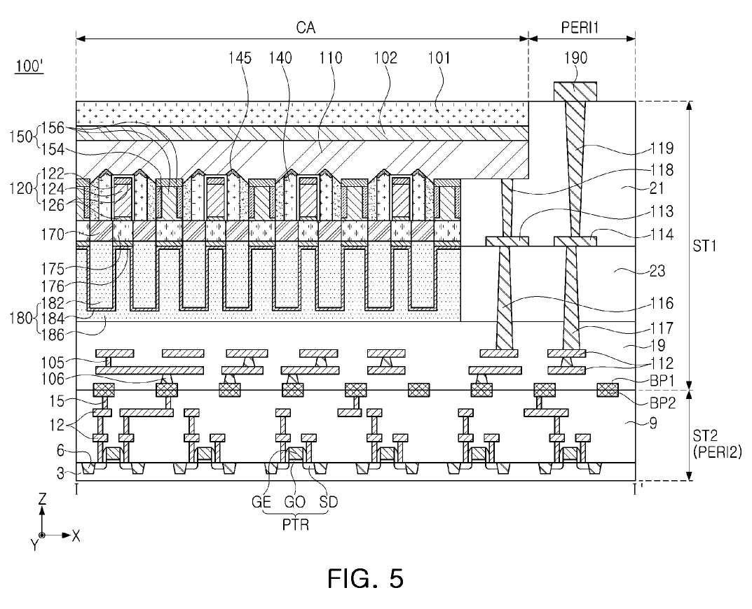

FIG. 5 is a vertical cross-sectional view taken along line I-I' of the semiconductor device of FIG. 2 according to another example embodiment.

Referring to FIG. 5, a semiconductor device 100’ may include a first structure ST1 and a second structure ST2 disposed below the first structure ST1. In an example, a memory cell array region CA and a first peripheral circuit region PERI1 may be disposed on a second peripheral circuit region PERI2 of the second structure ST2.

The semiconductor device 100’ may include a lower insulating layer 19 disposed below an information storage structure 180, the information storage structure 180, contact patterns 170 disposed on the information storage structure 180, first and second contact insulating patterns 175 and 176, active patterns 140 disposed on the contact patterns 170, word line structures 150, back gate structures 120, and a bit line structure 110 disposed on the active patterns 140 and extending in the first direction (X-direction). That is, the memory cell array region CA of the semiconductor device 100’ may include the information storage structure 180 disposed in a lower portion of the first structure ST1 and the bit line structure 110 disposed in an upper portion of the first structure ST1. The semiconductor device 100’ may further include a first substrate insulating layer 102 disposed on a bit line structure 110, and a first substrate 101 disposed on the first substrate insulating layer 102. The first substrate insulating layer 102 may be disposed between the first substrate 101 and the bit line structure 110. The first substrate 101 may include a bare silicon substrate.

The first structure ST1 of the semiconductor device 100’ may further include a second upper insulating structure 23 disposed on the lower insulating layer 19 and disposed on a side surface of the information storage structure 180, a first upper insulating structure 21 disposed on the second upper insulating structure 23, connection pads 114 disposed on the second upper insulating structure 23, upper pads 190 disposed on the first upper insulating structure 21, a lower contact plug 117 connecting the interconnection layers 112 and the connection pads 114, and an upper contact plug 119 connecting the connection pads 114 and the upper pads 190. The first upper insulating structure 21 may be disposed on a side surface of the first substrate 101, a side surface of the first substrate insulating layer 102, a side surface of the word line structure 150 disposed on an outermost edge, and a side surface of the second contact insulating pattern 176. An upper surface of the first substrate 101 may be coplanar with an upper surface of the first upper insulating structure 21.

The first structure ST1 of the semiconductor device 100’ may further include a bit line contact pad 113 disposed on the second upper insulating structure 23, a first bit line contact plug 116 connecting the interconnection layer 112 and the bit line contact pad 113, and a second bit line contact plug 118 connecting the bit line contact pad 113 and the bit line structure 110. The first bit line contact plug 116 may have a shape in which a width thereof becomes narrower toward an upper portion, and the second bit line contact plug 118 may have a shape in which a width thereof becomes narrower toward a lower portion.

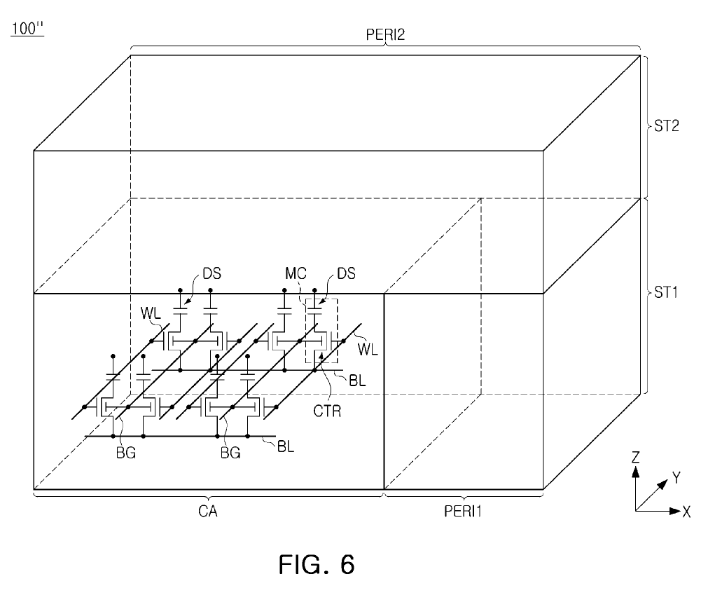

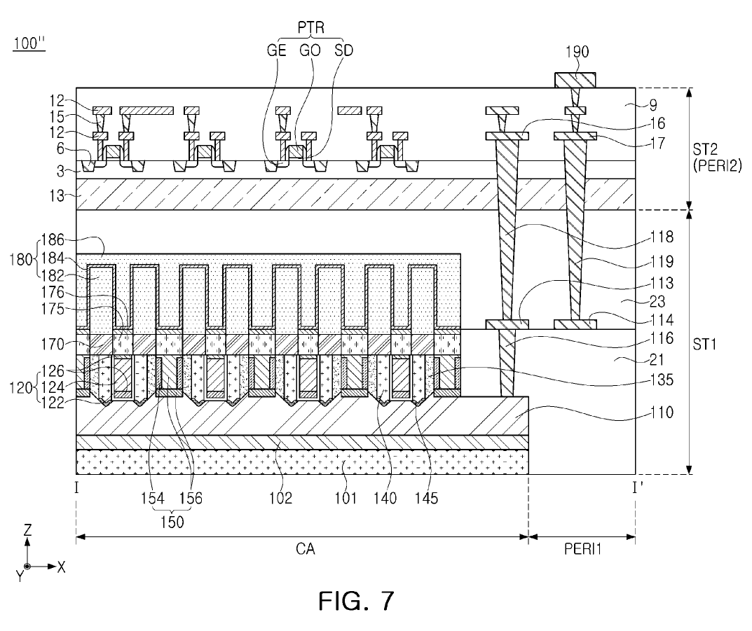

FIG. 6 is a schematic perspective view of a semiconductor device according to another example embodiment. FIG. 7 is a vertical cross-sectional view illustrating the semiconductor device of FIG. 6 according to an example embodiment . FIG. 7 is a vertical cross-sectional view taken along line I-I’ of the semiconductor device of FIG. 2 according to another example embodiment.

Referring to FIGS. 6 and 7, a semiconductor device 100” may include a first structure ST1 and a second structure ST2 disposed on the first structure ST1. The first structure ST1 may include a memory cell array region CA and a first peripheral circuit region PERI1. The second structure ST2 may include a second peripheral circuit region PERI2.

The memory cell array region CA of the semiconductor device 100” may include a first substrate 101, a first substrate insulating layer 102 on the first substrate 101, a bit line structure 110 disposed on the first substrate insulating layer 102, back gate structures 120, active patterns 140, word line structures 150, contact patterns 170, and an information storage structure 180. The memory cell array region CA of the semiconductor device 100’ may include an information storage structure 180 disposed in the upper portion of the first structure ST1 and a bit line structure 110 disposed in the lower portion of the first structure ST1.

The semiconductor device 100” may include a first upper insulating structure 21 disposed on the side surface of the bit line structure 110, the side surface of the word line structure 150 disposed on an outermost side, and a side surface of the second contact insulating pattern 176 disposed on an outermost side, a second upper insulating structure 23 disposed on a side surface and an upper surface of the information storage structure 180, a bit line contact pad 113 disposed on the first upper insulating structure 21, and a connection pad 114 disposed on the first upper insulating structure 21 and disposed on the same level as the bit line contact pad 113.

A second structure ST2 of the semiconductor device 100” may be disposed on the first structure ST1, and a second peripheral circuit region PERI2 of the second structure ST2 may include a second substrate insulating layer 13 disposed on the second upper insulating structure 23, a second substrate 3 on a second substrate insulating layer 13, a peripheral element isolation layer 6 and a peripheral transistor PTR disposed on an upper surface of the second substrate 3. The second structure ST2 may further include an upper insulating layer 9, interconnection layers 12, vias 15 , first and second interconnection lines 16 and 17 connected to the interconnection layers 12 and vias 15, and an upper pad 190 disposed on the upper insulating layer 9. The interconnection layers 12, the vias 15 and the first and second interconnection lines 16 and 17 may be buried in the upper insulating layer 9. The upper pad 190 and the second interconnection line 17 may be connected through the interconnection layer 12 and the vias 15.

The semiconductor device 100” may further include an upper contact plug 119 connecting the second interconnection line 17 and the connection pad 114, a first bit line contact plug 116 connecting the bit line structure 110 and the bit line contact pad 113, and a second bit line contact plug 118 connecting the first interconnection line 16 and the bit line contact pad 113.

The upper contact plug 119 may be connected to the connection pad 114 by penetrating through the upper insulating layer 9 below the second interconnection line 17, the second substrate 3, the second substrate insulating layer 13 and the second upper insulating structure 23. The first bit line contact plug 116 may be connected to the bit line structure 110 by penetrating through the first upper insulating structure 21 below the bit line contact pad 113. The second bit line contact plug 118 may be connected to the bit line contact pad 113 by penetrating through the upper insulating layer 9, the second substrate 3, the second substrate insulating layer 13 and the second upper insulating structure 23 below the first interconnection line 16. In an example, each of the upper contact plug 119 and each of the first bit contact plug 116 and the second bit line contact plug 118 may have a shape in which a width thereof becomes narrower toward a lower portion.

An upper surface of the second upper insulating structure 23 of the first structure ST1 may be bonded to a lower surface of the second substrate insulating layer 13 of the second structure ST2. An upper surface of the first structure ST1 and a lower surface of the second structure ST2 may be bonded to form a bonding surface. The first structure ST1 and the second structure ST2 of the semiconductor device 100” may be bonded to each other by dielectric-to-dielectric bonding.

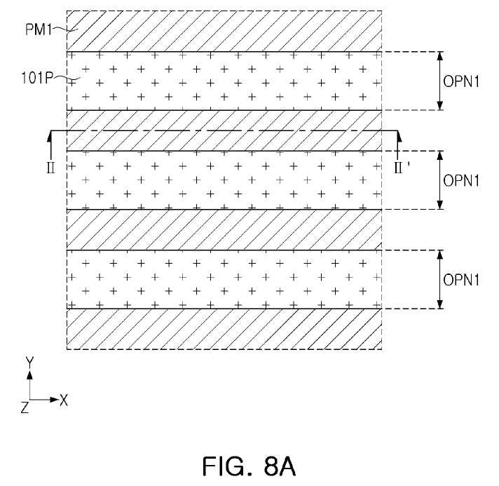

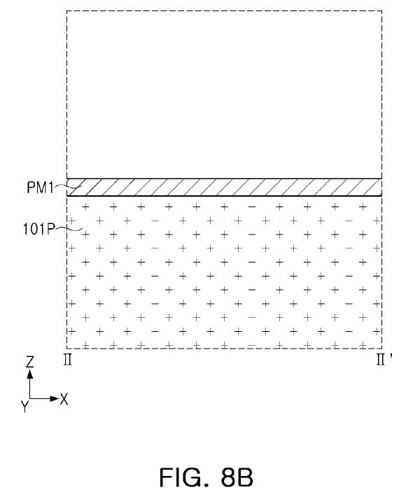

FIGS. 8A to 35 are cross-sectional views illustrating of a method of manufacturing the semiconductor device of FIG. 1 according to an example embodiment .

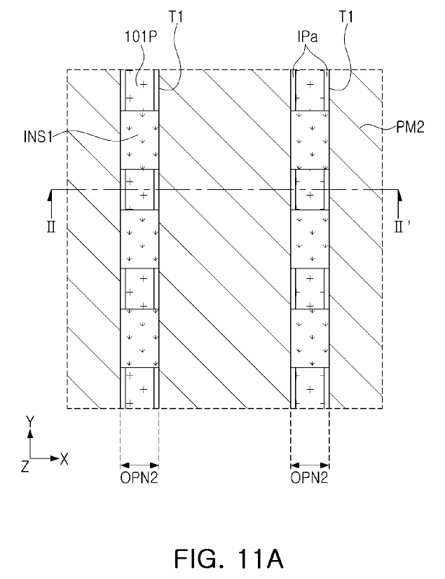

FIGS. 8A, 9, 10A and 11A are plan views illustrating a method of manufacturing a memory cell array region (e.g., a memory cell array region CA of FIG. 1) of a semiconductor device of FIG. 1. FIGS. 8B, 10B and 11B are vertical cross-sectional views taken along line II-II’ of the semiconductor device of FIGS. 8A, 10A and 11A, and FIGS. 12 to 36 are vertical cross-sectional views illustrating a method of manufacturing a semiconductor device after FIGS. 11A and 11B. FIGS. 8B, 10B, 11B and 12 to 35 illustrate vertical cross-sectional views corresponding to FIG. 4A.

Referring to FIGS. 8A and 8B, a semiconductor substrate 101P may be prepared, and a first mask pattern PM1 may be formed on the semiconductor substrate 101P. The first mask pattern PM1 may include first openings OPN1 extending in the first direction (X-direction) and spaced apart from each other in the second direction (Y-direction). An upper surface of the semiconductor substrate 101P may be exposed through the first openings OPN1.

In an example, the semiconductor substrate 101P may include a bare silicon substrate. The first mask pattern PM1 may include silicon oxide.

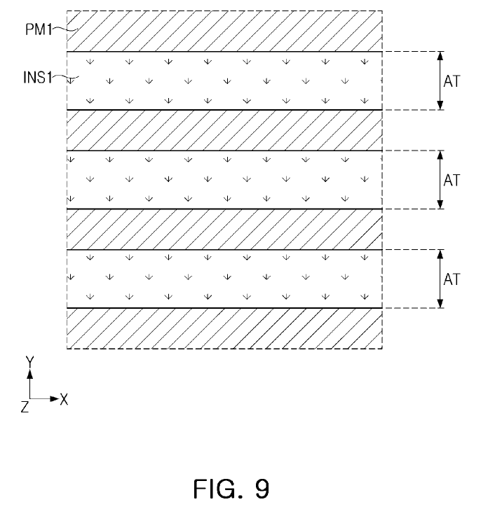

Referring to FIG. 9, a semiconductor substrate 101P may be etched using the first mask pattern PM1 as an etching mask to form auxiliary trenches AT, and a first insulating material INSb may be filled in the auxiliary trenches AT. An anisotropic dry etching process or a wet etching process may be performed on an upper surface of the semiconductor substrate 101P exposed through the first openings OPN1 of the first mask pattern PM1. The auxiliary trenches AT exposing a side surface and an upper surface of the semiconductor substrate 101P may be formed by the etching process, and each of the auxiliary trenches AT may extend in the first direction (X-direction) and may be spaced apart from each other in the second direction (Y-direction). The first insulating material INS1 filled in each of the auxiliary trenches AT may include at least one of silicon nitride, silicon oxide or silicon oxynitride.

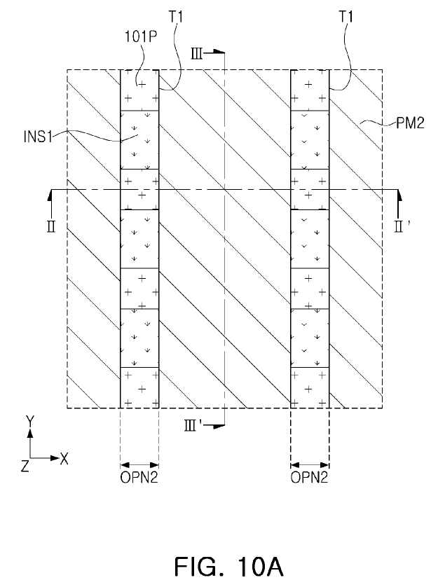

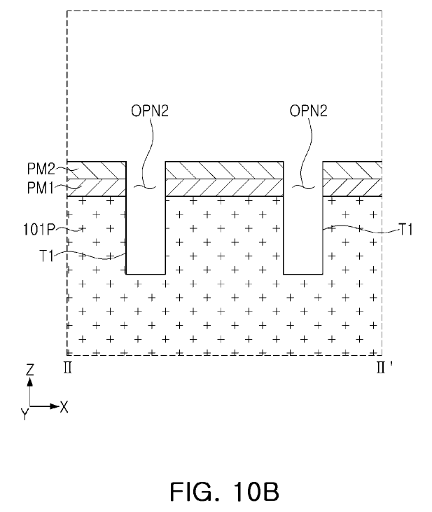

Referring to FIG. 10A and FIG. 10B, a second mask pattern PM2 may be formed on the first mask pattern PM1. The second mask pattern PM2 may be used as an etching mask to etch the first mask pattern PM1 and the semiconductor substrate 101P formed below the first mask pattern PM1 to form a first trench T1.

In an example, the second mask pattern PM2 may include second openings OPN2 extending in the second direction (Y-direction) and spaced apart from each other in the first direction (X-direction). The first insulating material INS1 and the first mask pattern PM1 may be exposed through the second openings OPN2. In an example, first trenches T1 may be formed by performing an anisotropic dry etching process or a wet etching process on the first mask pattern PM1 and the semiconductor substrate 101P below the first mask pattern PM1 exposed through the second openings OPN2 using the second mask pattern PM2 as an etching mask. The second mask pattern PM2 may include a material having etching selectivity with respect to the first mask pattern PM1. For example, the second mask pattern PM2 may include at least one of silicon nitride (SiN), silicon oxynitride (SiON), silicon oxycarbonitride (SiOCN), and/or silicon oxycarbide (SiOC). For example, the second mask pattern PM2 may include silicon oxynitride (SiON) and a material including carbon, for example, an Amorphous Carbon Layer (ACL). The first trench T1 may have a constant width in the vertical direction (Z-direction).

Referring to FIGS. 11A and 11B, an insulating liner IPa conformally covering a sidewall of the first trench T1 may be formed. The insulating liner IPa may be formed according to a surface profile of the sidewall of the first trench T1. A bottom surface of the semiconductor substrate 101P in the first trench T1 may be exposed from the insulating liner IPa. The insulating liner IPa may include an insulating material including silicon nitride. The insulating liner IPa may be formed using a deposition process. For example, the deposition process may include a physical vapor deposition (PVD) process, a chemical vapor deposition (CVD) process, or an atomic layer deposition (ALD) process.

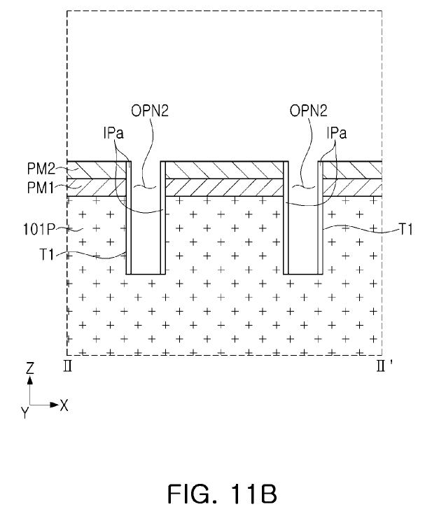

Referring to FIG. 12, a second trench T2 may be formed by an etching process on a bottom surface within the first trench T1. A sidewall of the second trench T2 may be disposed further inside than the sidewall of the first trench T1 in which an insulating liner IPa is formed. The second trench T2 may be formed by an isotropic etching process on the bottom surface within the first trench T1. A second width of the second trench T2 in the first direction (X-direction) may be greater than a first width of the first trench T1 in the first direction (X-direction). In an example, the second trench T2 may be adjacent to a lower surface of a semiconductor substrate 101P below the first trench T1. In an example, a vertical length of the sidewall of the first trench T1 may be longer than a vertical length of the sidewall of the second trench T2. However, the present disclosure is not limited thereto, and a vertical length of the sidewall of the first trench T1 may be equal to or less than a vertical length of the sidewall of the second trench T2. In this document, the first trench T1 and the second trench T2 may be referred to as ‘trench structures.’

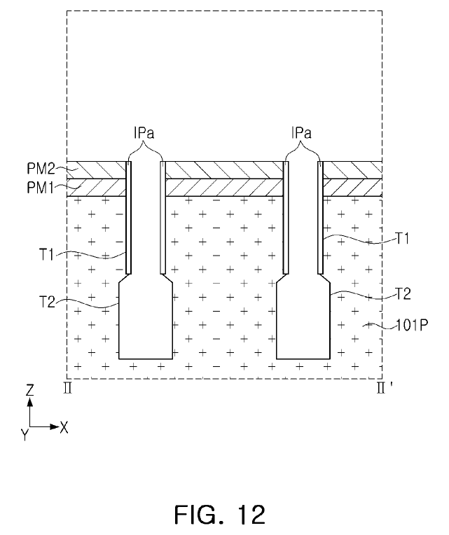

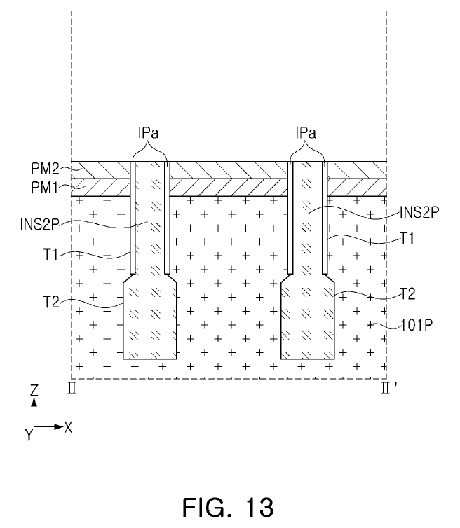

Referring to FIG. 13, the first trench T1 and the second trench T2 may be filled with a second insulating material INS2P. The second insulating material INS2P may include an insulating material including silicon oxide.

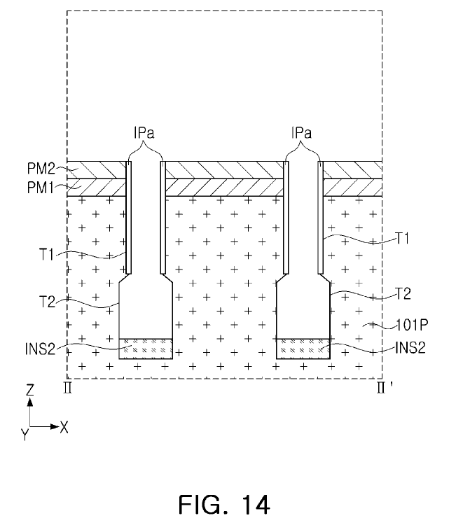

Referring to FIG. 14, the second insulating material INS2P may be partially etched to expose the insulating liner IPa and a portion of the sidewall of the second trench T2. The second insulating material INS2P formed in the first trench T1 may be removed to expose the insulating liner IPa, and a portion of the second insulating material INS2P formed in the second trench T2 may be removed to expose a portion of the sidewall of the second trench T2. As the second insulating material INS2P is partially etched, the second insulating material INS2P may remain as a first substrate insulating pattern INS2 covering the bottom surface of the second trench T2.

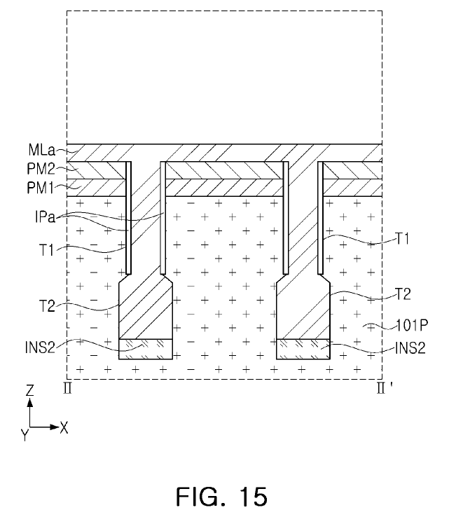

Referring to FIG. 15, a first conductive material MLa may be formed in the first and second trenches T1 and T2 on the first substrate insulating pattern INS2. The first conductive material MLa may cover the second mask pattern PM2 and may fill an interior of the first and second trenches T1 and T2. The first conductive material MLa may include a conductive material. For example, the first conductive material MLa may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or combinations thereof.

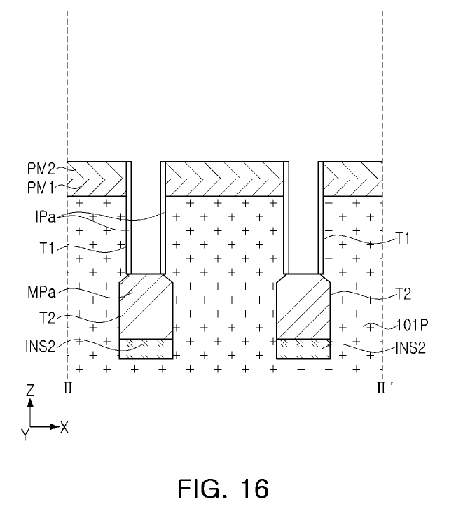

Referring to FIG. 16, a first conductive pattern MPa may be formed by removing the remaining first conductive material MLa except for a first conductive material MLa formed in the second trench T2. An upper surface of the second mask pattern PM2 of FIG. 15 and the first conductive material MLa formed in the first trench T1 may be removed. As a portion of the first conductive material MLa is etched, the first conductive material MLa in the second trench T2 may remain as the first conductive pattern MPa on the first substrate insulating pattern INS2.

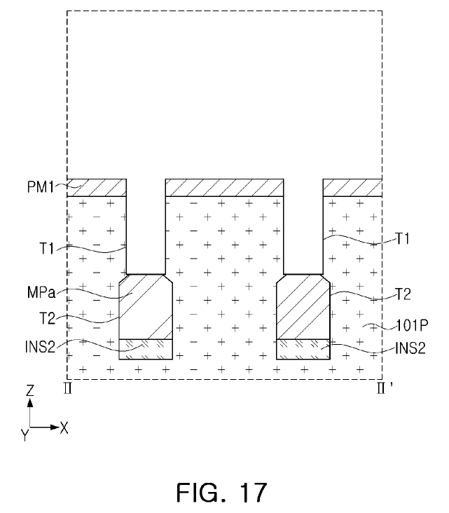

Referring to FIG. 17, the second mask pattern PM2 may be removed to expose an upper surface of the first mask pattern PM1, and the insulating liner IPa may be removed to expose a sidewall of the first trench T1.

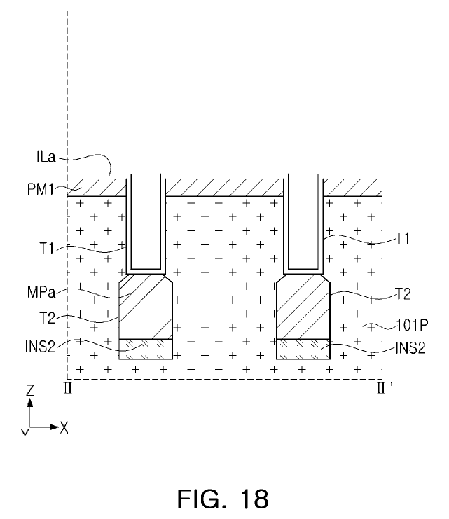

Referring to FIG. 18, a first insulating layer ILa conformally covering the upper surface of the first mask pattern PM1, the sidewall of the first trench T1 and an upper surface of the first conductive pattern MPa may be formed. The first insulating layer ILa may be formed by the deposition process mentioned with reference to FIGS. 11A and 11B.

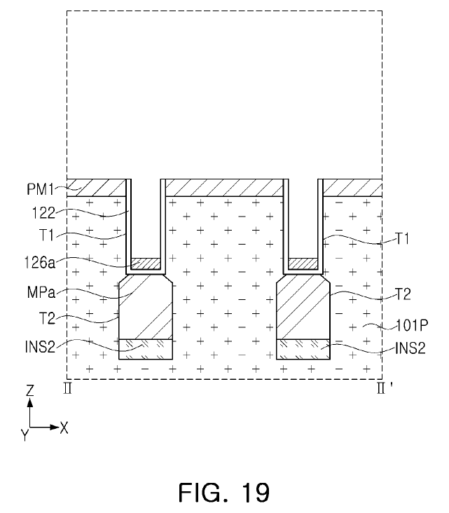

Referring to FIG. 19, the first insulating layer ILa formed on the upper surface of the first mask pattern PM1 may be removed to expose the upper surface of the first mask pattern PM1. The first insulating layer ILa conformally covering the sidewall of the first trench T1 and the upper surface of the first conductive pattern MPa may remain as a back gate dielectric layer 122. A lower back gate capping pattern 126a may be formed within the first trench T1. The lower back gate capping pattern 126a may be formed on the back gate dielectric layer 122 overlapping the upper surface of the first conductive pattern MPa. A vertical length of the lower back gate capping pattern 126a may be less than a vertical length of the first trench T1. The back gate dielectric layer 122 of FIG. 19 may correspond to the back gate dielectric layer 122 of FIG. 4A, and the lower back gate capping pattern 126a may correspond to the lower back gate capping pattern of FIG. 4A.

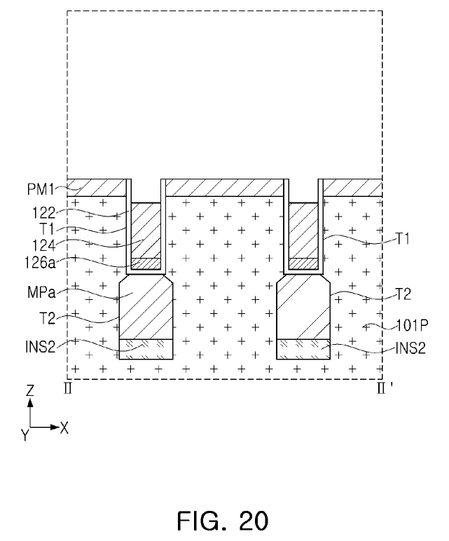

Referring to FIG. 20, the back gate electrode 124 may be formed on the lower back gate capping pattern 126a. The lower surface of the back gate electrode 124 may be in contact with the lower back gate capping pattern 126a, and the side surface of the back gate electrode 124 may be surrounded by the back gate dielectric layer 122. The upper surface of the back gate electrode 124 may be disposed on a level lower than the upper surface of the semiconductor substrate 101P. In an example, a vertical length of the back gate electrode 124 may be less than a vertical length of the first trench T1. The back gate electrode 124 of FIG. 20 may correspond to the back gate electrode 124 of FIG. 4A.

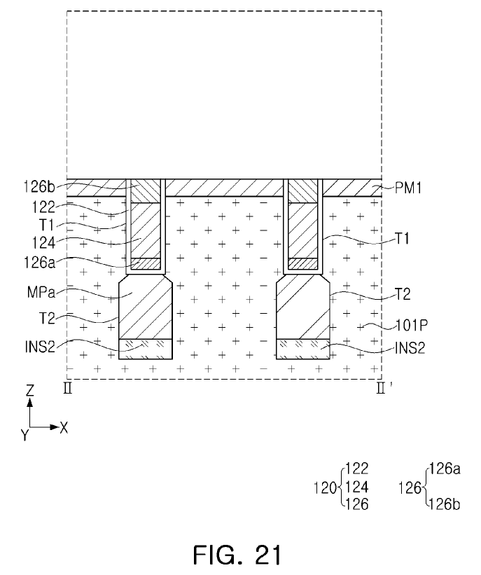

Referring to FIG. 21, an upper back gate capping pattern 126b may be formed on the back gate electrode 124. A lower surface of the upper back gate capping pattern 126b may be in contact with the upper surface of the back gate electrode 124, and a side surface of the upper back gate capping pattern 126b may be surrounded by the back gate dielectric layer 122. An upper surface of the upper back gate capping pattern 126b may be coplanar with the upper surface of the first mask pattern PM1. The upper back gate capping pattern 126b of FIG. 21 may correspond to the upper back gate capping pattern 126b of FIG. 4A. The back gate electrode 124, the lower back gate capping pattern 126a, the upper back gate capping pattern 126b and the back gate dielectric layer 122 may form a back gate structure 120.

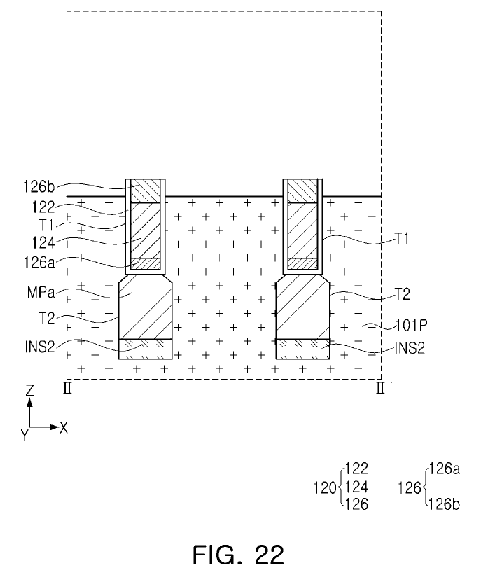

Referring to FIG. 22, the first mask pattern PM1 may be removed to expose the upper surface of the semiconductor substrate 101P and a side surface of the back gate dielectric layer 122 protruding onto the upper surface of the semiconductor substrate 101P.

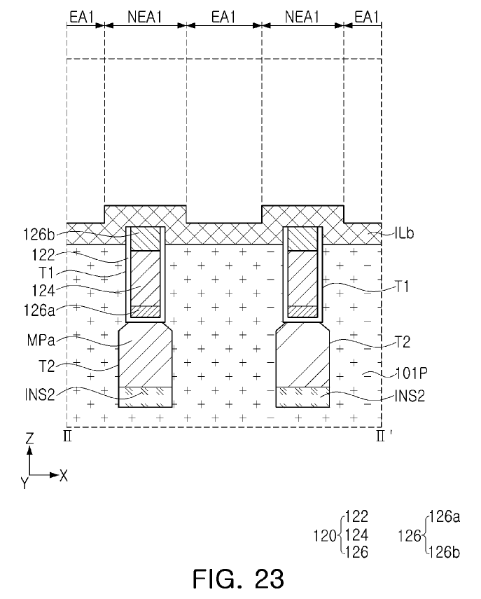

Referring to FIG. 23, a first spacer layer ILb covering the upper surface of the semiconductor substrate 101P, the side surface of the back gate dielectric layer 122 and the upper surface of the upper back gate capping pattern 126b by a uniform thickness may be formed. A width of a protruding portion 101b of a semiconductor substrate 101P’ described below may be determined according to a thickness of the first spacer layer ILb. The first spacer layer ILb may be formed of an insulating material. For example, silicon oxide, silicon oxynitride, silicon nitride, silicon carbide, and combinations thereof may be used as the first spacer layer ILb.

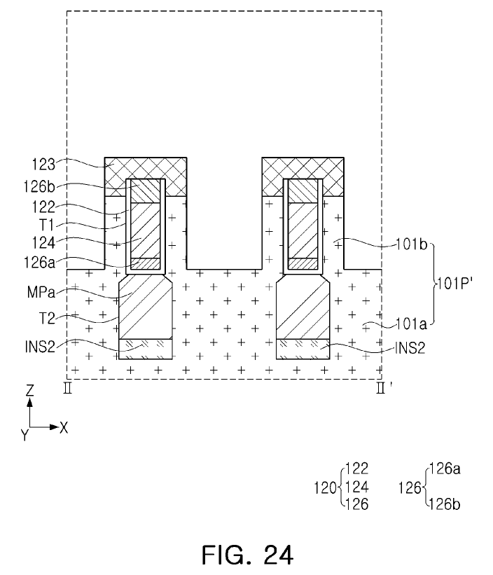

Referring to FIGS. 23 and 24, the first spacer layer ILb may include a first etched region EA1 covering the semiconductor substrate 101P and a first non-etched region NEA1 covering the side surface of the back gate dielectric layer 122 and the upper surface of the upper back gate capping pattern 126b. An anisotropic etching process may be performed on the first etched region EA1 of the first spacer layer ILb to remove the first etched region EA1 of the first spacer layer ILb and a portion of the semiconductor substrate 101P overlapping the first etched region EA1. By removing the portion of the semiconductor substrate 101P overlapping the first etched region EA1, the semiconductor substrate 101P’ may be formed.

The semiconductor substrate 101P’ may include a body portion 101a surrounding the first substrate insulating pattern INS2 and the first conductive pattern MPa, and protruding portions 101b protruding from the upper surface of the body portion 101a and separated from each other on both sides of the back gate structures 120. The first spacer layer ILb may remain as a first spacer pattern 123 corresponding to the first non-etched region NEA1 as the first etched region EA1 is removed. The first spacer pattern 123 may surround the side surface of the back gate dielectric layer 122 and the upper surface of the upper back gate capping pattern 126b on the protruding portions 101b.

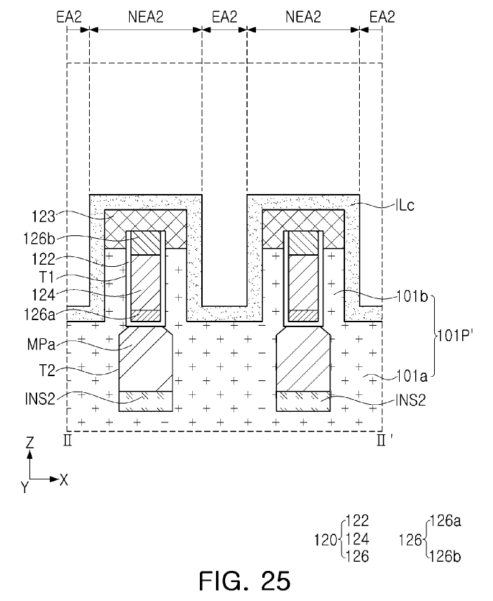

Referring to FIG. 25, a second spacer layer ILc covering the upper surface of the body portion 101a, a side surface of the protruding portions 101b protruding from the upper surface of the body portion 101a, and a side surface and an upper surface of the first spacer pattern 123 by a uniform thickness may be formed.

The second spacer layer ILc may include the same material as the first spacer pattern 123, but the present disclosure is not limited thereto. For example, the second spacer layer ILc may be formed of, for example, silicon oxide, silicon oxynitride, silicon nitride, silicon carbide, and combinations thereof. In another example, the second spacer layer ILc may include at least one of a high-κ dielectric. The high-κ dielectric may include a metal oxide or a metal oxynitride. For example, the high-κ dielectric may be formed of HfO₂, HfSiO, HfSiON, HfTaO, HfTiO, HfZrO, ZrO₂, Al₂O₃, or combinations thereof, but the present disclosure is not limited thereto.

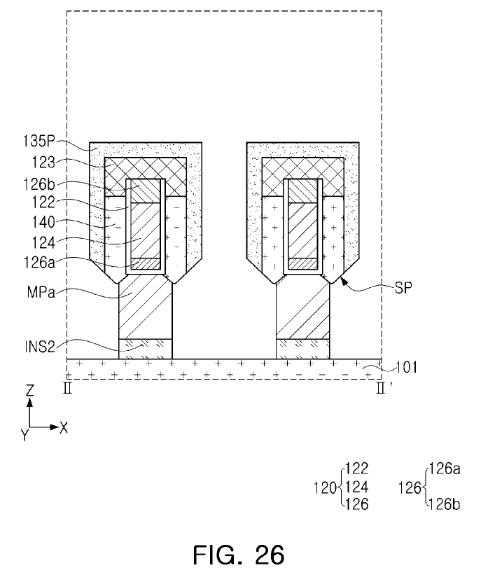

Referring to FIGS. 25 and 26, the second spacer layer ILc may include a second etched region EA2 covering the semiconductor substrate 101P’ and a second non-etched region NEA2 covering the side surface of the protruding portions 101b and the side surface and the upper surface of the first spacer pattern 123. An etching process on the second etched region EA2 of the second spacer layer ILc may be performed to remove the second etched region EA2 of the second spacer layer ILc and a portion of the semiconductor substrate 101P’ overlapping the second etched region EA2.

In an example, through the etching process for the second etched area EA2 of the second spacer layer ILc, as the body portion 101a connected to the protruding portions 101b of the semiconductor substrate 101P’ is removed, the protruding portions 101b may remain as active patterns 140 formed on both sides of each of the word line structures 150, and the body portion 101a of the semiconductor substrate 101P’ may remain as the semiconductor substrate 101 forming a coplanar surface with the lower surface of the first substrate insulating pattern INS2. In an example, as the body portion 101a surrounding a side surface of the first conductive pattern MPa and a side surface of the first substrate insulating pattern INS2 is removed, the side surface of the first conductive pattern MPa and the side surface of the first substrate insulating pattern INS2 may be exposed from the first substrate 101. The second spacer layer ILc may remain as a second spacer pattern 135P corresponding to the second non-etched region NEA2 as the second etched region EA2 is removed. In a process in which the semiconductor substrate 101P’ overlapping the second etched region EA2 is etched in a horizontal direction to expose the side surface of the first conductive pattern MPa and the side surface of the first substrate insulating pattern INS2, a lower surface of the second spacer pattern 135P may have an inclined surface SP due to a selective etching ratio of the second spacer layer ILc to the protruding portions 101b.

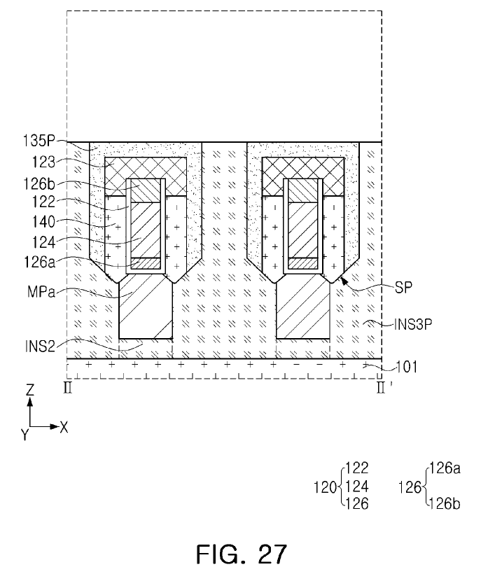

Referring to FIG. 27, a third insulating material INS3P may be formed on the first substrate 101. The third insulating material INS3P may be formed on the side surface of the first substrate insulating pattern INS2, the side surface of the first conductive pattern MPa and a lower surface and a side surface of the second spacer pattern 135P. An upper surface of the third insulating material INS3P may be coplanar with an upper surface of the second spacer pattern 135P. In an example, the third insulating material INS3P may include the same insulating material as the second insulating material INS2P of FIG. 13. However, the present disclosure is not limited thereto, and the third insulating material INS3P may include an insulating material including silicon oxide.

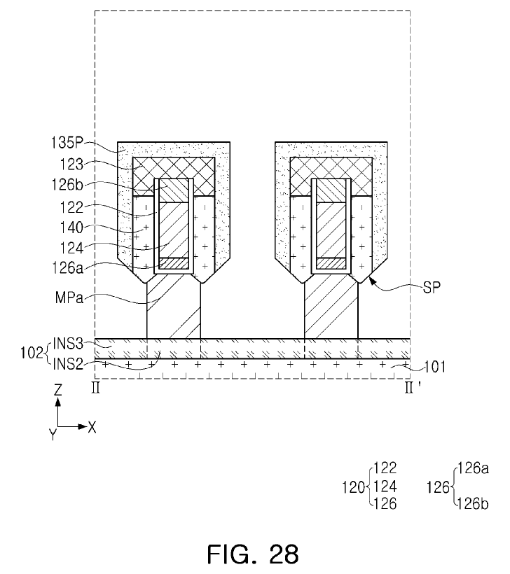

Referring to FIG. 28, the third insulating material INS3P may be etched to expose the side surface of the first conductive pattern MPa and a side surface and the lower surface of the second spacer pattern 135P. In some etching processes on the third insulating material INS3P, the remaining third insulating material INS3P may remain as a second substrate insulating pattern INS3 forming a coplanar surface with an upper surface of the first substrate insulating pattern INS2. In an example, the first substrate insulating pattern INS2 and the second substrate insulating pattern INS3 may form a first substrate insulating layer 102.

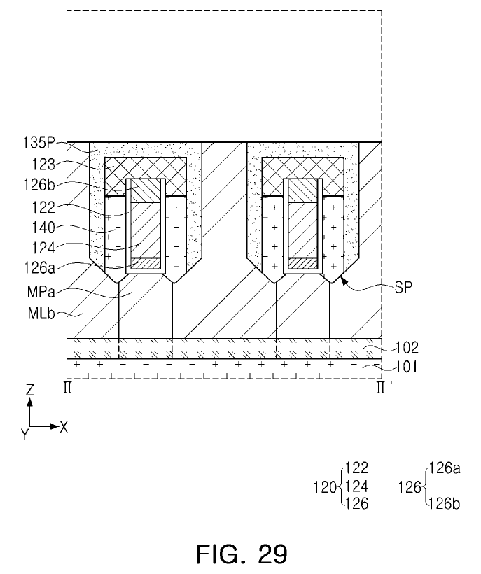

Referring to FIG. 29, a second conductive material MLb may be formed on the first substrate insulating layer 102. The second conductive material MLb may be formed on the side surface of the first conductive pattern MPa and the lower surface and the side surface of the second spacer pattern 135P on the first substrate insulating layer 102. An upper surface of the second conductive material MLb may form a coplanar surface with the upper surface of the second spacer pattern 135P. The second conductive material MLb may include the same conductive material as the first conductive material MLa of FIG. 15. However, the present disclosure is not limited thereto, and the second conductive material MLb may be formed of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or combinations thereof.

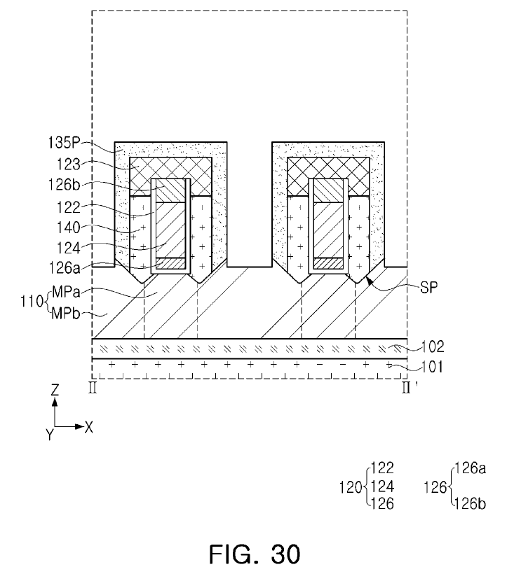

Referring to FIG. 30, the second conductive material MLb may be etched to expose at least a portion of the side surface of the second spacer pattern 135P. In some etching processes for the second conductive material MLb, the remaining second conductive material MLb may cover a lower surface of the active patterns 140 and the lower surface of the second spacer pattern 135P, and may remain as a second conductive pattern MPb disposed on the side surface of the first conductive pattern MPa. The upper surface of the first conductive pattern MPa may be disposed on a lower level than an upper surface of the second conductive pattern MPb exposed between the second spacer patterns 135P. In another example, the second conductive pattern MPb may cover a portion of the side surface of the second spacer pattern 135P. In this case, a maximum vertical level of the inclined surface SP of the second spacer pattern 135P may be disposed on a lower level than the upper surface of the second conductive pattern MPb. The first conductive pattern MPa and the second conductive pattern MPb may form the bit line structure 110 of FIG. 4A. The silicide pattern 145 of FIG. 4A may be formed in a portion of the first conductive pattern MPa in contact with a lower surface of each of the active patterns 140 and in a portion of the second conductive pattern MPb in contact with a lower surface of each of the active patterns 140.

A portion of the first conductive pattern MPa vertically overlapping the back gate structure 120 may correspond to the first portion 110a of the bit line structure 110 of FIG. 4A, and a portion of the first conductive pattern MPa vertically overlapping the active patterns 140, a portion of the second conductive pattern MPb vertically overlapping the active patterns 140, and a portion of the second conductive pattern MPb vertically overlapping the second spacer pattern 135P may correspond to the third portion 110c of the bit line structure 110 of FIG. 4A.

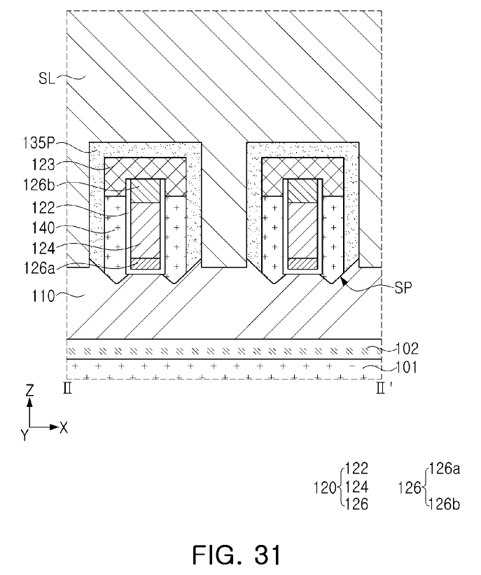

Referring to FIG. 31, a sacrificial layer SL may be formed on the second conductive pattern MPb exposed between side surfaces of the second spacer pattern 135P. The sacrificial layer SL may be formed to cover the upper surface of the second conductive pattern MPb and the side surface and the upper surface of the second spacer pattern 135P. The above sacrificial layer SL may include a material including carbon. For example, the sacrificial layer SL may include a Spin-on Hardmask (SOH) and/or an Amorphous Carbon Layer (ACL).

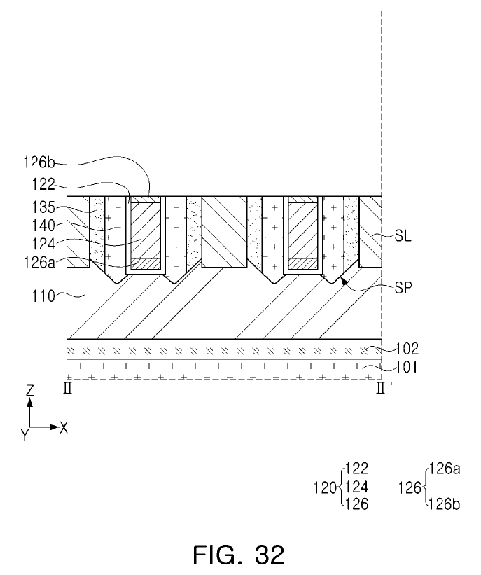

Referring to FIGS. 31 and 32, a flattening process may be performed so that upper surfaces of the active patterns 140 are exposed. In an example, the flattening process may be performed on the sacrificial layer SL, the back gate dielectric layer 122, the upper back gate capping pattern 126b, the first spacer pattern 123 and the second spacer pattern 135P until the upper surfaces of the active patterns 140 are exposed. Through the planarization process, the first spacer pattern 123 on the active patterns 140 may be removed. The sacrificial layer SL formed on a level lower than the upper surface of the active pattern 140 may remain surrounded by the insulating pattern 135 on the second conductive pattern MPb. The second spacer pattern 135P may remain as the insulating pattern 135 formed on a side surface of the active patterns 140. The upper surface of the active pattern 140 may be coplanar with an upper surface of the insulating pattern 135 and the upper surface of the upper back gate capping pattern 126b. The insulating pattern 135 of FIG. 32 may correspond to the insulating pattern 135 of FIG. 4A.

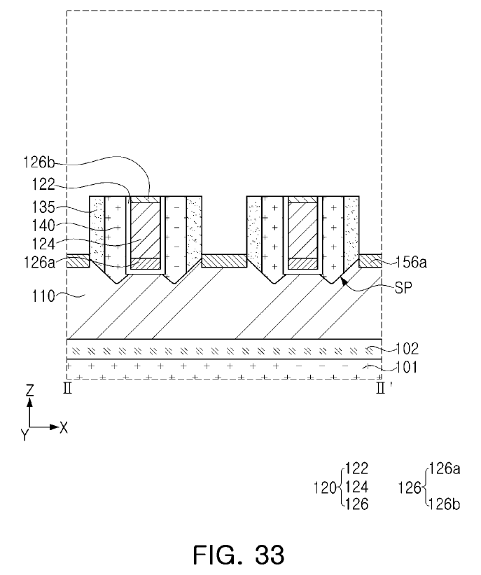

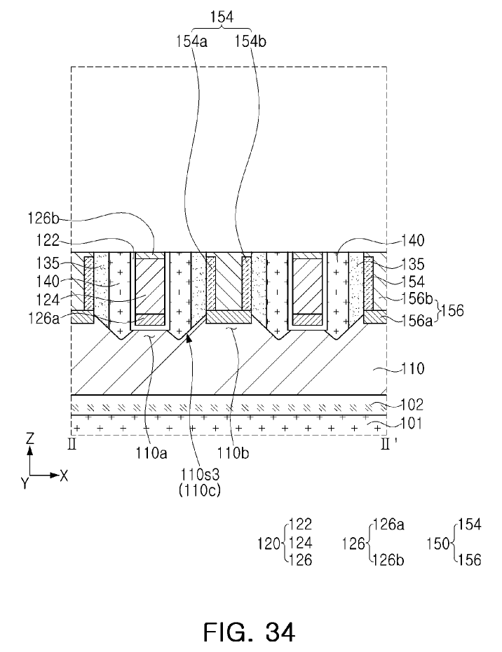

Referring to FIGS. 33 and 34, the remaining sacrificial layer SL of FIG. 32 may be removed, and a word line structure 150 may be formed on the bit line structure 110 exposed between the insulating patterns 135. Referring to FIG. 33, a lower gate capping pattern 156a may be formed on the bit line structure 110 exposed between the insulating patterns 135. Referring to FIG. 34, a first word line 154a and a second word line 154b spaced apart from each other in the first direction (X-direction) may be formed on the lower gate capping pattern 156a, and an upper gate capping pattern 156b may be formed between the first word line 154a and the second word line 154b and on the first and second word lines 154a and 154b. The word lines 154 including the first and second word lines 154a and 154b and the gate capping patterns 156 including the lower gate capping pattern 156a and upper gate capping patterns 156b may form a word line structure 150.

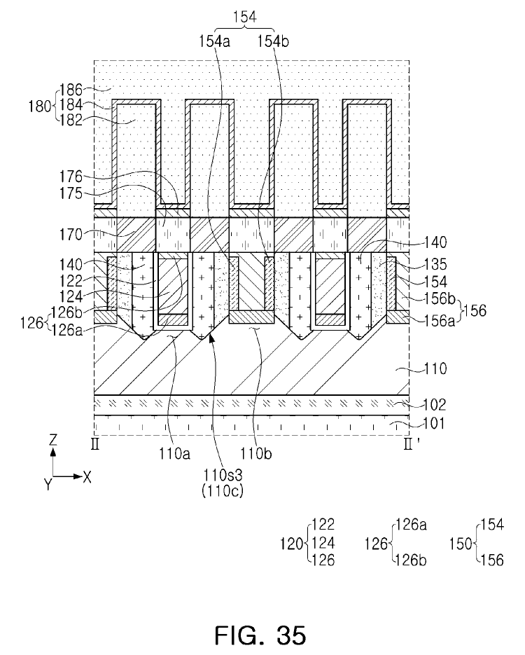

Referring to FIG. 35, contact patterns 170 may be formed on the active patterns 140, and an information storage structure 180 may be formed on the contact patterns 170. The method of manufacturing a semiconductor device may further include forming first contact insulating patterns 175 between the contact patterns 170, and forming second contact insulating patterns 176 on the first contact insulating patterns 175. In an example embodiment, an operation of removing the first substrate insulating layer 102 and the semiconductor substrate 101 below the bit line structure 110 after forming the information storage structure 180 and an operation of forming an interconnection structure (e.g., vias 105, contact vias 106, interconnection layer 112 and first bonding pads BP1 of FIG. 3) below the bit line structure 110 may be performed. In another example, a process of forming interconnection structures (e.g., vias 105, contact vias 106, interconnection layer 112 and first bonding pads BPbof FIG. 5) on the information storage structure 180 after forming the information storage structure 180, or a process of bonding a second upper insulating structure 23 to the second structure ST2 after forming the second upper insulating structure 23 on the information storage structure 180 may be performed.

Although the present disclosure has been described above with reference to embodiments thereof, it will be understood by those skilled in the art that various modifications and changes may be made to the present disclosure without departing from the concept and scope of the present disclosure as set forth in the claims.

What is claimed is:

1. A semiconductor device, comprising:
a bit line structure extending in a first direction;
back gate structures disposed on the bit line structure and respectively including a back gate electrode;
word line structures disposed alternately with the back gate structures in the first direction, each of the word line structures including a first word line and a second word line, adjacent to each other in the first direction;
active patterns disposed between the back gate structures and the word line structures and connected to the bit line structure;
contact patterns disposed on each of the active patterns and connected to each of the active patterns; and
information storage structures disposed on the contact patterns,
wherein the bit line structure includes a first portion vertically overlapping each of the back gate structures, a second portion vertically overlapping each of the word line structures, and a third portion contacting each of the active patterns between the first portion and the second portion and having an inclined surface.

2. The semiconductor device of claim 1, wherein an upper surface of the first portion is disposed at a lower level than an upper surface of the second portion.

3. The semiconductor device of claim 1, wherein the inclined surface increases in height toward each of the word line structures.

4. The semiconductor device of claim 1, wherein a lower surface of each of the active patterns is shaped to protrude toward a lower surface of the third portion of the bit line structure.

5. The semiconductor device of claim 1, wherein a lower surface of each of the active patterns is disposed at a lower level than an upper surface of the first portion of the bit line structure.

6. The semiconductor device of claim 1, wherein each of the back gate structures further comprises:
a back gate dielectric layer extending laterally from a lower surface of the back gate electrode;
a lower back gate capping pattern disposed between the back gate dielectric layer and the back gate electrode; and
an upper back gate capping pattern disposed on the back gate electrode,
wherein a lower surface of the back gate dielectric layer is in contact with an upper surface of the first portion of the bit line structure.

7. The semiconductor device of claim 1, further comprising:
a silicide pattern disposed between a lower surface of each of the active patterns and the third portion of the bit line structure.

8. The semiconductor device of claim 1, wherein each of the word line structures further comprises:
a lower gate capping pattern in contact with a lower surface of the first word line and a lower surface of the second word line; and
an upper gate capping pattern disposed between the first word line and the second word line, and covering an upper surface of the first word line and an upper surface of the second word line.

9. The semiconductor device of claim 8, wherein a lower surface of the lower gate capping pattern is buried in the second portion.

10. The semiconductor device of claim 8, wherein a lower surface of the lower gate capping pattern is in contact with an upper surface of the second portion.

11. The semiconductor device of claim 1, further comprising:
insulating patterns disposed between the word line structures and the active patterns,
wherein a lower surface of each of the insulating patterns is in contact with the inclined surface of the third portion.

12. The semiconductor device of claim 1, wherein a vertical length of the second portion of the bit line structure is greater than a vertical length from a lower surface of the bit line structure to a lower surface of each of the active patterns.

13. A semiconductor device, comprising:
a bit line structure extending in a first direction;
a first active pattern, a second active pattern, and a third active pattern sequentially arranged on the bit line structure in the first direction and connected to the bit line structure;
a back gate structure disposed between the first active pattern and the second active pattern, and including a back gate dielectric layer and a back gate electrode disposed on the back gate dielectric layer;
a word line structure disposed between the second active pattern and the third active pattern;
contact patterns disposed on each of the first, second and third active patterns and connected to the first, second and third active patterns; and
an information storage structure disposed on the contact patterns,
wherein the bit line structure includes a first portion vertically overlapping the back gate structure and a second portion vertically overlapping the word line structure, and
an upper surface of the first portion and an upper surface of the second portion are disposed at different levels.

14. The semiconductor device of claim 13, wherein a lower surface of each of the first, second and third active patterns is disposed at a lower level than an upper surface of the first portion and an upper surface of the second portion.

15. The semiconductor device of claim 13, wherein a lower surface of each of the first, second and third active patterns has a shape in which a width thereof becomes narrower toward a lower surface of the bit line structure.

16. The semiconductor device of claim 13, wherein the word line structure comprises:
a lower gate capping pattern;
a first word line facing one side of the second active pattern on the lower gate capping pattern; and
a second word line facing one side of the third active pattern on the lower gate capping pattern and spaced apart from the first word line in the first direction,
wherein a lower surface of the lower gate capping pattern is in contact with the second portion.

17. The semiconductor device of claim 13, wherein the bit line structure further includes a third portion having an inclined surface between the first portion and the second portion,
wherein a lower surface of the second active pattern is contact with the inclined surface of the third portion.

18. The semiconductor device of claim 17, wherein a vertical level of the inclined surface of the third portion increases toward the word line structure.

19. The semiconductor device of claim 13, further comprising:
a substrate insulating layer disposed below a lower surface of the bit line structure; and
a bare silicon substrate disposed below a lower surface of the substrate insulating layer.

20. A semiconductor device, comprising:
a first structure including a memory cell array region; and
a second structure vertically overlapping the first structure and including a peripheral circuit region,
wherein the memory cell array region comprises:
a bit line structure extending in a first direction;
a word line structure disposed on the bit line structure, and including a gate capping pattern and a first word line and a second word line, adjacent to each other in the first direction on the gate capping pattern;
active patterns disposed on the bit line structure and disposed on both sides of the word line structure;
insulating patterns disposed between each of the word line structures and each of the active patterns;
contact patterns disposed on each of the active patterns and connected to each of the active patterns; and
an information storage structure disposed on the contact patterns,
wherein the bit line structure includes a portion having an inclined surface which is in contact with lower surfaces of each of the insulating patterns and has a vertical level that increases toward the word line structure.
